(19) United States
(12) Patent Application Publication
(10) Pub. No.: US 2017/0010529 A1
(43) Pub. Date: Jan. 12, 2017

(54) COLORING COMPOSITION, CURED FILM, COLOR FILTER, PATTERN FORMING METHOD, METHOD FOR MANUFACTURING COLOR FILTER, SOLID-STATE IMAGING DEVICE, AND IMAGE DISPLAY DEVICE

(71) Applicant: FUJIFILM Corporation, Tokyo (JP)

(72) Inventor: Kaoru AOYAGI, Haibara-gun (JP)

(73) Assignee: FUJIFILM Corporation, Tokyo (JP)

(21) Appl. No.: 15/272,565

(22) Filed: Sep. 22, 2016

Related U.S. Application Data
(63) Continuation of application No. PCT/JP2015/058333, filed on Mar. 19, 2015.

(30) Foreign Application Priority Data
Mar. 26, 2014 (JP) 2014-064593

(51) Int. Cl. G03F 7/00; C08K 5/3417; G03F 7/16; G02F 1/1335; G03F 7/30; C08G 77/04; G02B 5/22; C08K 5/00; G03F 7/20

(52) U.S. Cl. CPC G03F 7/0007; C08K 5/0041; C08K 5/3417; G03F 7/168; G03F 7/20; G03F 7/30; C08G 77/04; G02B 5/223; G02F 1/133514

(57) ABSTRACT

Provided are a coloring composition which hardly causes warping or the like to occur in a substrate to which the coloring composition has been applied, and is capable of forming a cured film or the like having excellent colorfastness; and a cured film, a color filter, a pattern forming method, a method for manufacturing a color filter, a solid-state imaging device, and an image display device, each using such a coloring composition.

A coloring composition containing a colorant and a resin, in which the content of the colorant with respect to the total solid content of the coloring composition is 60% by mass or more, the resin contains at least a siloxane resin having Si—OH bonds and Si—OR¹ bonds in the total number of 0.2 to 1.0 bonds per silicon atom, and the content of the siloxane resin with respect to the total solid content of the coloring composition is 1% by mass to 20% by mass. Here, R¹ represents an alkyl group or an aryl group.

### CROSS-REFERENCE TO RELATED APPLICATIONS

This application is a Continuation of PCT International Application No. PCT/JP2015/058333 filed on Mar. 19, 2015, which claims priority under 35 U.S.C §119(a) to Japanese Patent Application No. 2014-064593 filed on Mar. 26, 2014. The above application is hereby expressly incorporated by reference, in its entirety, into the present application.

### BACKGROUND OF THE INVENTION

1. Field of the Invention

The present invention relates to a coloring composition. The present invention further relates to a cured film, a color filter, a pattern forming method, a method for manufacturing a color filter, a solid-state imaging device, and an image display device, each using the coloring composition.

2. Description of the Related Art

Recently, in accordance with the development of personal computers, in particular, large-screen liquid crystal televisions, liquid crystal displays (LCD), in particular, color liquid crystal displays tend to be in increased demand. Organic EL displays are required to be distributed due to a demand for an additional increase in high quality. Meanwhile, as digital cameras and camera-mounted mobile phones are distributed, demands for solid-state imaging devices such as a CCD image sensor are also greatly increased.

Color filters are used as key devices of the displays or optical elements, and the demand for higher quality and cost reduction is increasing. Such color filters usually comprise colored patterns with three colors of red (R), green (G), and blue (B), and divides light that passes through display devices or imaging devices into three colors.

As a method for manufacturing a color filter, photolithography is often used. The photolithography is a method which includes applying a colored radiation-sensitive composition onto a support, followed by drying, to form a colored layer, and then subjecting this colored layer to pattern exposure/development, or the like to form a colored pixel (colored pattern) with the first tint, which applies to formation of colored pixels in the remaining colors.

Moreover, a method for forming a colored pattern by a dry etching method is also known.

For example, JP2010-78834A discloses a method for manufacturing a color filter, including aligning colored layers in at least two colors on the surface of a substrate, in which the method includes a colored layer forming step of applying a composition containing a colorant containing organopolysilsesquioxane onto a support to form a colored layer, a photoresist layer forming step of forming a photoresist layer on the colored layer, a patterning step of subjecting the photoresist layer to a photolithography treatment to perform patterning according to a predetermined pattern, an etching step of carrying out a dry etching treatment by using the photoresist layer as a mask, a photoresist removing step of removing the residual photoresist layer, and an etch-back step of subjecting a plurality of colored layers including the colored layers formed by the colorant layer forming step simultaneously to an entire-surface dry etching treatment, in which the etching rates at a time of etching the plurality of colored layers are made uniform in the etch-back step.

On the other hand, JP2012-87316A discloses that a siloxane-based resin composition containing at least one metal compound particle selected from the group consisting of aluminum compound particles, tin compound particles, titanium compound particles, and zirconium compound particles, and a siloxane compound is used in optical parts such as a microlens and an antireflection film, and the like.

### SUMMARY OF THE INVENTION

For a coloring composition for use in formation of a color filter, further improvement of colorfastness is demanded.

Furthermore, the present inventors have manufactured a color filter using a coloring composition including a siloxane resin, and could see that if the content of Si—OH bonds or Si—OR bonds in the siloxane resin is high, warping occurs in a substrate to which the coloring composition has been applied during the curing of coloring composition in some cases. Based on this, in the case where a colored pattern with a first tint is formed using a coloring composition including a siloxane resin, and then colored patterns with the remaining colors are formed, recognition failure of wafer alignment might occur in some cases during the exposure of the colored layers in the remaining colors.

On the other hand, JP2012-87316A discloses that optical parts such as microlens and an antireflection film are formed using a siloxane resin composition, but has no description that a color filter and the like are formed using the siloxane resin composition.

Therefore, the present invention has an object to provide a coloring composition which hardly causes warping or the like to occur in a substrate to which the coloring composition has been applied, and is capable of forming a cured film or the like having excellent colorfastness; and a cured film, a color filter, a pattern forming method, a method for manufacturing a color filter, a solid-state imaging device, and an image display device, each using such a coloring composition.

The present inventors have extensively studied and as a result, they have found that by incorporating a siloxane resin containing Si—OH bonds and Si—OR¹ bonds in the total number of 0.2 to 1.0 bonds per silicon atom into a coloring composition, warping or the like hardly occurs in a substrate to which the coloring composition has been applied and a cured film having excellent colorfastness can be formed. Specifically, the problems were solved by the following means <1>, and preferably by <2> to <11>.

<1> A coloring composition comprising:

a colorant; and

a resin,

in which the content of the colorant with respect to the total solid content of the coloring composition is 60% by mass or more,

the resin contains a siloxane resin containing Si—OH bonds and Si—OR¹ bonds (in which R¹ represents an alkyl group or an aryl group) in the total number of 0.2 to 1.0 bonds per silicon atom, and the content of the siloxane resin with respect to the total solid content of the coloring composition is 1% by mass to 20% by mass.

<2> The coloring composition as described in <1>, in which the siloxane resin contains 0.6 to 1.5 Si—R² bonds (in which R² represents an alkyl group or an aryl group) per silicon atom.

<3> The coloring composition as described in <1> or <2>, further comprising a curable compound.

<4> The coloring composition as described in any one of <1> to <3>, in which the colorant contains at least a halogenated zinc phthalocyanine pigment.

<5> The coloring composition as described in any one of <1> to <4>, for use in formation of a colored layer of a color filter.

<6> A cured film formed by curing the coloring composition as described in any one of <1> to <5>.

<7> A color filter comprising the cured film as described in <6>.

<8> A pattern forming method comprising:

a step of applying the coloring composition as described in any one of <1> to <5> onto a support, followed by drying, to form a colored layer;

a step of curing the colored layer;

a step of forming a photoresist on the cured colored layer;

a step of patterning the photoresist by exposing and developing the photoresist; and

a step of patterning the colored layer of the underlayer of the photoresist by dry etching, using the patterned photoresist as an etching mask.

<9> A method for manufacturing a color filter having a plurality of colored layers formed on a substrate, comprising:

a step of forming the pattern of a first colored layer in accordance with the method as described in <8>; and

a step of forming another colored pattern by lithography on the first colored layer thus patterned.

<10> A solid-state imaging device comprising the color filter as described in <7> or a color filter obtained by the method for manufacturing a color filter as described in <9>.

<11> An image display device comprising the color filter as described in <7> or a color filter obtained by the method for manufacturing a color filter as described in <9>.

According to the present invention, it is possible to provide a coloring composition which hardly causes warping or the like to occur in a substrate to which the coloring composition has been applied, and is capable of forming a cured film or the like having excellent colorfastness. Further, it is also possible to provide a cured film, a color filter, a pattern forming method, a method for manufacturing a color filter, a solid-state imaging device, and an image display device, using such the coloring composition.

### BRIEF DESCRIPTION OF THE DRAWINGS

FIG. 1 is a schematic cross-sectional view of a first colored layer.

FIG. 2 is a schematic cross-sectional view showing a state where a photoresist layer is formed on the first colored layer.

FIG. 3 is a schematic cross-sectional view showing a state where a resist pattern is formed on the first colored layer.

FIG. 4 is a schematic cross-sectional view showing a state where a first colored pattern is formed by providing a through-hole group on the first colored layer by etching.

FIG. 5 is a schematic cross-sectional view showing a state where the resist pattern in FIG. 4 is removed.

FIG. 6 is a schematic cross-sectional view showing a state where a second colored pattern and a second colored layer are formed.

FIG. 7 is a schematic cross-sectional view showing a state where second colored pixels constituting the second colored layer and the second colored pattern in FIG. 6 are partially removed.

FIG. 8 is a schematic cross-sectional view showing a state where a third colored pattern and a third colored layer are formed.

FIG. 9 is a schematic cross-sectional view showing a state where the third colored layer in FIG. 8 is removed.

### DESCRIPTION OF THE PREFERRED EMBODIMENTS

Hereinafter, the disclosures of the present invention will be described in detail. In the present specification, “(a value) to (a value)” is used in a meaning that the numeric values described before and after are included as the lower limit value and the upper limit value. Further, the organic EL element in the present invention refers to an organic electroluminescence element.

In the present specification, the total solid content refers to a total mass of the components remaining when a solvent is excluded from the entire composition of a coloring composition. Further, the solid content refers to a solid content at 25° C. In addition, the viscosity is a value measured in the state where the temperature is adjusted to 25° C.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

Furthermore, “radiation” in the present specification means, for example, a bright line spectrum of a mercury lamp, far ultraviolet rays represented by an excimer laser, extreme ultraviolet rays (EUV rays), X-rays, electron beams, or the like. In addition, in the present invention, light means actinic rays or radiation. “Exposure” in the present specification includes, unless otherwise specified, not only exposure by a bright line spectrum of a mercury lamp, far ultraviolet rays represented by an excimer laser, X-rays, EUV rays, or the like, but also writing by particle rays such as electron beams and ion beams.

Moreover, in the present specification, “(meth)acrylate” represents either or both of acrylate and methacrylate, “(meth)acryl” represents either or both of acryl and methacryl, and “(meth)acryloyl” represents either or both of acryloyl and methacryloyl.

In addition, in the present specification, a “monomeric material” and a “monomer” have the same definition. The monomer in the present specification refers to a compound which is distinguished from an oligomer or a polymer and has a weight-average molecular weight of 2,000 or less. In the present specification, a polymerizable compound refers to a compound having a polymerizable functional group, and may be a monomer or a polymer. The polymerizable functional group refers to a group involved in a polymerization reaction.

In the present specification, Me represents a methyl group, Et represents an ethyl group, Pr represents a propyl group, Bu represents a butyl group, and Ph represents a phenyl group in formulae.

In the present specification, a term “step” includes not only an independent step, but also steps which are not clearly distinguished from other steps if an intended action of the steps is obtained.

In the present specification, the weight-average molecular weight and the number-average molecular weight are defined as a value in terms of polystyrene by GPC measurement. In the present specification, the weight-average molecular weight (Mw) and the number-average molecular weight (Mn) can be determined, for example, using HLC-8220 (manufactured by Tosoh Corporation) and TSKgel Super AWM-H (manufactured by Tosoh Corporation, 6.0 mm ID×15.0 cm) as a column, and a 10 mmol/L solution of lithium bromide in N-methylpyrrolidinone (NMP) as an eluant.

The pigment for use in the present invention means an insoluble colorant compound that is hardly dissolved in a solvent. Typically, it means a colorant compound that is present in the state where it is dispersed as particles in the present composition. Here, the solvent includes any solvents, and examples thereof include the solvents exemplified in the section of a solvent which will be described later.

<Coloring Composition>

The coloring composition of the present invention is a coloring composition including a colorant and a resin, in which the content of the colorant with respect to the total solid content of the coloring composition is 60% by mass or more, the resin contains at least a siloxane resin containing Si—OH bonds and Si—OR¹ bonds (in which R¹ represents an alkyl group or an aryl group) in the total number of 0.2 to 1.0 bonds per silicon atom, and the content of the siloxane resin with respect to the total solid content of the coloring composition is 1% by mass to 20% by mass.

According to the present invention, warping or the like hardly occurs in a substrate to which the coloring composition has been applied, and a cured film or the like having excellent colorfastness can be formed. The reason why such effects of the present invention are obtained is that the siloxane resin for use in the present invention contains Si—OH bonds and Si—OR¹ bonds in the total number of 0.2 to 1.0 bonds per silicon atom, and thus, curing of the siloxane resin during the curing of coloring composition can proceed appropriately. By this, the resistance to chemicals such as a developing liquid and a stripping liquid increases, and thus, a cured film having excellent colorfastness can be formed. In addition, it is thought that since the curing proceeds appropriately, the curing shrinkage of the siloxane resin could be inhibited, and thus, the warping of the substrate to which a coloring composition has been applied could be inhibited.

Hereinafter, the coloring composition of the present invention will be described in detail.

<<Siloxane Resin>>

The coloring composition of the present invention contains a siloxane resin.

The siloxane resin for use in the present invention preferably contains Si—OH bonds and Si—OR¹ bonds in the total number of 0.2 to 1.0, preferably 0.3 to 0.9, more preferably 0.45 to 0.85, and particularly preferably 0.6 to 0.75, per silicon atom. By setting the total sum of the numbers of Si—OH bonds and Si—OR¹ bonds to the ranges, the curing of the siloxane resin during the curing of coloring composition can proceed appropriately. By this, a cured film having excellent colorfastness can be formed. In addition, the curing shrinkage of the siloxane resin can be inhibited, and thus, the warping of the substrate to which a coloring composition has been applied can be inhibited.

The number of Si—OH bonds per silicon atom is preferably 0.15 to 0.45, and more preferably 0.3 to 0.35. Further, the number of Si—OR¹ bonds per silicon atom is preferably 0.15 to 0.45, and more preferably 0.3 to 0.35.

Furthermore, R¹ represents an alkyl group or an aryl group. The number of carbon atoms of the alkyl group is preferably 1 to 20, more preferably 1 to 10, and still more preferable 1 to 5. The number of carbon atoms of the aryl group is preferably 6 to 20, and more preferably 6 to 12. R¹ is preferably a methyl group.

The siloxane resin for use in the present invention preferably contains 0.6 to 1.5 Si—R² bonds, more preferably 0.7 to 1.2 Si—R² bonds, and particularly preferably 0.8 to 1.1 Si-R² bonds, per silicon atom.

The number of carbon atoms of the Si—R² bonds per silicon atom can be accomplished by adjusting the use ratio of the silane compounds represented by Formulae (1) to (3) which will be described later, in the production of the siloxane resin. For example, by increasing the use ratio of the silane compound represented by Formula (3) which will be described later, the number of Si—R² bonds per silicon atom can be decreased. Further, by increasing the ratio of the silane compound represented by Formula (1) which will be described later to, the number of Si—R² bonds per silicon atom can be increased.

In addition, R² represents an alkyl group or an aryl group. The number of carbon atoms of the alkyl group is preferably 1 to 20, more preferably 1 to 10, and still more preferably 1 to 5. The number of carbon atoms of the aryl group is preferably 6 to 20, and more preferably 6 to 12. R² is preferably a methyl group.

The number of the Si—OH bonds, the Si—OR¹ bonds, and the Si—R² bonds of the siloxane resin can be calculated from the area ratio of peaks obtained by NMR measurement.

The weight-average molecular weight of the siloxane resin is preferably 1,000 to 100,000, more preferably 2,000 to 50,000, and particularly preferably 5,000 to 30,000.

In the coloring composition of the present invention, the content of the siloxane resin is 1% by mass to 20% by mass, and preferably 1% by mass to 15% by mass, with respect to the total solid content of the coloring composition.

<<<Production of Siloxane Resin>>>

The siloxane resin can be produced through a hydrolysis reaction and a condensation reaction, using an alkoxysilane as a raw material.

In order to produce the siloxane resin, for example, the silane compounds represented by the following Formulae (1) to (3) can be used as a starting raw material.

Si(OR¹)₂R²₂ (1)

Si(OR¹)₃R²₁ (2)

Si(OR¹)₄ (3)

In Formulae (1) to (3), R¹ and R² each independently represent an alkyl group or an aryl group.

The number of carbon atoms of the alkyl group is preferably 1 to 20, more preferably 1 to 10, and still more preferably 1 to 5, and particularly preferably, the alkyl group is a methyl group.

The number of carbon atoms of the aryl group is preferably 6 to 20, and more preferably 6 to 12.

In the case where the compound has 2 or more R¹'s and R²'s, a plurality of R¹'s and R²'s may be the same as or different from each other.

Examples of the silane compound represented by Formula (1) include dimethyldimethoxysilane, dimethyldiethoxysilane, diphenyldimethoxysilane, diphenyldiethoxysilane, and methylphenyldimethoxysilane.

Examples of the silane compound represented by Formula (2) include methyltrimethoxysilane, methyltriethoxysilane, methyltri-n-propoxysilane, methyltriisopropoxysilane, methyltri-n-butoxysilane, methyltriisobutoxysilane, methyltri-tert-butoxysilane, ethyltrimethoxysilane, ethyltriethoxysilane, hexyltrimethoxysilane, octadecyltrimethoxysilane, octadecyltriethoxysilane, phenyltrimethoxysilane, phenyltriethoxysilane, and phenyltriisopropoxysilane.

Examples of the silane compound represented by Formula (3) include tetramethoxysilane, tetraethoxysilane, tetra-n-propoxysilane, tetraisopropoxysilane, tetra-n-butoxysilane, tetraisobutoxysilane, and tetra-tert-butoxysilane.

The silane compounds may be used singly or in combination of two or more kinds thereof.

For example, the number of the Si—R² bonds per silicon atom of the obtained siloxane resin can be accomplished by adjusting the ratio of the silane compounds represented by Formulae (1) to (3) to be used in the production of the siloxane resin. For example, by increasing the ratio of the silane compound represented by Formula (3), the number of Si—R² bonds per silicon atom can be decreased. Further, by increasing the use ratio of the silane compound represented by Formula (1), the number of Si—R² bonds per silicon atom can be increased.

For the hydrolysis reaction and condensation reaction for obtaining the siloxane resin, a known method can be used, and if desired, a catalyst may be used.

Examples of the catalyst used in the hydrolysis reaction and the condensation reaction include metal oxides including Al, Zn, Ti, and Sn, acids, alkalis, and boron compounds.

Examples of the metal oxides including Al, Zn, Ti, and Sn aluminum isopropoxide.

Examples of the acids (organic acids or inorganic acids) include nitric acid, oxalic acid, acetic acid, formic acid, hydrochloric acid, and boric acid.

Examples of the alkalis include ammonia, triethylamine, and ethylenediamine.

Examples of the boron compound include alkoxyborane (trialkoxyborane and the like).

The amount of the catalyst to be used is not particularly limited, but is preferably 0.1 parts by mass to 10 parts by mass, with respect to 100 parts by mass of the silane compound. The catalysts may be used singly or in combination of two or more kinds thereof.

To the reaction system of the hydrolysis reaction and the condensation reaction, a solvent may be added, if desired, The solvent is not particularly limited as long as the hydrolysis reaction and the condensation reaction can be carried out therewith, and as the solvent, for example, water or the organic solvents which will be described later are preferably used.

As the conditions (temperature, time, or amount of the solvent) for the hydrolysis reaction and the condensation reaction, optimal conditions are appropriately selected according to the types of the materials to be used.

<<Other Siloxane Resins>>

The coloring composition of the present invention may contain siloxane resins other than the siloxane resins (hereinafter also referred to as other siloxane resins). Examples of such other siloxane resins include many of siloxane resins having the total number of the Si—OH bonds and the Si—OR¹ bonds per silicon atom of less than 0.2, and siloxane resins having the total number of the Si—OH bonds and the Si—OR¹ bonds per silicon atom of more than 1.0.

Examples of the siloxane resins having the total number of the Si—OH bonds and the Si—OR¹ bonds per silicon atom of less than 0.2 include the organopolysilsesquioxanes described in paragraph Nos. 0048 to 0050 of JP2010-78834A.

The amount of such other siloxane resins is preferably 10 parts by mass or less, and more preferably 5 parts by mass or less with respect to 100 parts by mass of the above-mentioned siloxane resins, and particularly preferably, such other siloxane resins are substantially not contained. “Being substantially not contained” is, for example, preferably 1 part by mass or less, and more preferably 0.5 parts by mass or less, with respect to 100 parts by mass of the above-mentioned siloxane resins, and it is particularly preferable that such other siloxane resins are not contained.

The coloring composition of the present invention may further include resins other than the siloxane resin. For example, in the case where a pigment such as a halogenated zinc phthalocyanine pigment is included as a colorant, a resin that functions as a dispersing agent may be contained in order to improve the dispersibility of the pigment. Further, it can be configured such that the above-mentioned siloxane resin also functions as a dispersing agent of a pigment such as a halogenated zinc phthalocyanine pigment.

Furthermore, the resin may further include the siloxane resins for use in the present invention, such as an alkali-soluble resin, the above-mentioned other siloxane resins, and resins other than a resin as a dispersing agent.

In the coloring composition of the present invention, the content of all the siloxane resins in the total amount of the resin is preferably 10% by mass to 100% by mass, and more preferably 20% by mass to 100% by mass.

<<Colorant>>

The coloring composition of the present invention contains a colorant. As the colorant, a pigment, a dye, or the like can be used. Among these, a colorant including a halogenated zinc phthalocyanine pigment can be preferably used.

<<<Halogenated Zinc Phthalocyanine Pigment>>>

The halogenated zinc phthalocyanine pigment is a halogenated phthalocyanine pigment having zinc as a central metal, in which the pigment has a planar structure in which zinc as a central metal is positioned within a region surrounded by four nitrogen atoms of an isoindole ring, as represented by the following General Formula (A1).

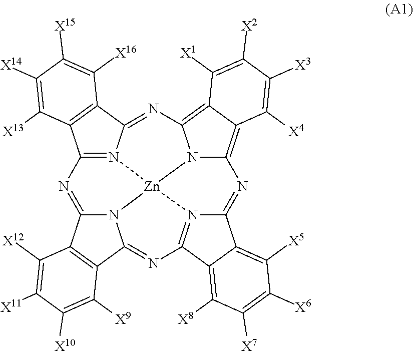

In General Formula (A1), it is preferable that any 8 to 16 positions of X¹ to X¹⁶ each represent a halogen atom, and the residues each represent a hydrogen atom or a substituent. It is preferable that in X¹ to X¹⁶, the number of halogen atoms is 8 to 12. Further, it is preferable that X¹ to X¹⁶ include at least one of a chlorine atom, a bromine atom, or a hydrogen atom. In addition, it is preferable that the number of chlorine atoms is 0 to 4, the number of bromine atoms is 8 to 12, and the number of hydrogen atoms is 0 to 4.

Those represented by halogen atoms in X¹ to X¹⁶ may be all the same halogen atoms.

Examples of the halogen atom include a chlorine atom, a bromine atom, a fluorine atom, and an iodine atom, and in particular, a bromine atom and a chlorine atom are preferable.

For the substituent, reference can be made to the descriptions of paragraph Nos. 0025 to 0027 of JP2013-209623A, the contents of which will be incorporated herein by reference.

For the halogenated zinc phthalocyanine pigment, reference can be made to, for example, the descriptions of paragraph Nos. 0013 to 0039, and 0084 to 0085 of JP2007-284592A, the contents of which will be incorporated herein by reference.

Examples of the halogenated zinc phthalocyanine pigment include C. I. Pigment Green 58 as a compound classified into a pigment in Color Index (C. I.; published by The Society of Dyers and Colourists). The average composition of C. I. Pigment Green 58 is as follows: out of X¹ to X¹⁶, 9.8 members are bromine atoms, 3.1 members are chlorine atoms, and 3.1 members are hydrogen atoms.

In the coloring composition of the present invention, the content of the halogenated zinc phthalocyanine pigment with respect to the total solid content in the coloring composition is preferably 10% by mass to 80% by mass, more preferably 15% by mass to 70% by mass, and particularly preferably 20% by mass to 70% by mass.

Furthermore, the content of the halogenated zinc phthalocyanine pigment in the total amount of the colorant is preferably 10% by mass to 100% by mass, more preferably 20% by mass to 90% by mass, and particularly preferably 30% by mass to 80% by mass. The halogenated zinc phthalocyanine pigment may be used singly or in combination of two or more kinds thereof. Further, X¹ to X¹⁶ of General Formula (A1) may include different combinations of two or more kinds of the compounds. In the case of including two or more kinds, the total amount is within the range.

<<<Other Colorants>>>

The colorant included in the coloring composition of the present invention may be a colorant other than the halogenated zinc phthalocyanine pigment (hereinafter also referred to as other colorants). Further, it may be used in combination of the halogenated zinc phthalocyanine pigment and other colorants, and preferably includes other colorants. Other colorants may be either a dye or a pigment, and both may be used in combination.

Examples of the pigment include various inorganic pigments or organic pigments known in the art. Further, when it is considered that either inorganic or organic pigments having a high transmittance are preferable, pigments having an average particle diameter which is as small as possible are preferably used, and when the handleability is also considered, the average particle diameter of the pigments is preferably 0.01 μm to 0.1 μm, and more preferably 0.01 μm to 0.05 μm.

Examples of the organic pigments include the following pigments, but the present invention is not limited thereto.

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like,

C. I. Pigment Orange 2, 5, 13, 16, 17:1, 31, 34, 36, 38, 43, 46, 48, 49, 51, 52, 55, 59, 60, 61, 62, 64, 71, 73, and the like,

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279,

C. I. Pigment Green 7, 10, 36, and 37,

C. I. Pigment Violet 1, 19, 23, 27, 32, 37, and 42,

C. I. Pigment Blue 1, 2, 15, 15:1, 15:2, 15:3, 15:4, 15:6, 16, 22, 60, 64, 66, 79, and 80, and

C. I. Pigment Black 1.

These organic pigments may be used singly or in combination of various pigments to improve the color purity.

Among those, C. I. Pigment Yellow 129, 138, 150, and 185 are preferable, and C. I. Pigment Yellow 150 is more preferable.

Examples of the inorganic pigment include metal compounds represented by a metal oxide, a metal complex salt, or the like, and specific examples thereof include black pigments such as carbon black and titanium black, metal oxides of iron, cobalt, aluminum, cadmium, lead, copper, titanium, magnesium, chromium, zinc, antimony, and the like, and complex oxides of the above metals.

As the dye, the dyes described in JP1989-90403A (JP-S64-90403A), JP1989-91102A (JP-S64-91102A), JP1989-94301A (JP-H01-94301A), JP1994-11614A (JP-H06-11614A), JP2592207B, U.S. Pat. No. 4,808,501A, U.S. Pat. No. 5,667,920A, US505950A, JP1993-333207A (JP-H05-333207A), JP1994-35183A (JP-H06-35183A), JP1994-51115A (JP-H06-51115A), JP1994-194828A (JP-H06-194828A), and the like can be used. As categorized according to the chemical structures, a pyrazolazo compound, a pyrromethene compound, an anilinoazo compound, a triphenylmethane compound, an anthraquinone compound, a benzylidene compound, an oxonol compound, a pyrazolotriazolazo compound, a pyridonazo compound, a cyanine compound, a phenothiazine compound, a pyrrolopyrazolazomethine compound, or the like can be used. In addition, as the dye, a colorant multimer may be used. Examples of the colorant multimer include the compounds disclosed in JP2011-213925A and JP2013-041097A.

A content of the colorant with respect to the total solid content in the coloring composition of the present invention is 60% by mass or more, preferably 60% by mass to 90% by mass, and particularly preferably 65% by mass to 85% by mass. By setting the content of the colorant to 60% by mass or more, the colorant concentration in the solid content is increased, and thus, the crosstalk (color mixing of light) can be reduced when the color filter is made into a finer film. Further, in the case where dry etching is carried out using the coloring composition of the present invention, the etching rate decreases at a time of forming a pattern by dry etching. Accordingly, the difference in the etching rates between the upper part and the lower part of the pattern is decrease, and therefore, the perpendicularity of the pattern to a substrate is increased, and thus, the rectangularity is improved. In addition, as a result, the uniformity in film thickness of the colored pattern formed by etching is increased, and thus, the surface roughness at the time of a planarization treatment is inhibited. In addition, due to a high colorant concentration, the strength of the colored layer is increased, and thus, the surface roughness caused by the planarization treatment due to a polishing treatment such as a CMP treatment can also be reduced. As a result, the coloring composition of the present invention can be preferably used as a coloring composition for dry etching.

One kind or two or more kinds of the colorants may be included. In the case where two or more kinds of the colorants are included, the total amount thereof is preferably within the range.

<<Other Resins>>

The coloring composition of the present invention may contain a resin to disperse colorants such as a pigment. Such a resin acts as a dispersing agent.

The resin that acts as a dispersing agent is preferably substantially composed of only an acid type resin or a base type resin. When the resin that acts as a dispersing agent is composed of only an acid type resin or a base type resin, the dispersibility of the pigment can be further improved. Above all, it is particularly preferable that the resin that acts as a dispersing agent is substantially composed of only an acid type resin. Further, the expression of “being substantially composed of only an acid type resin” preferably means that the content of the resins other than the acid type resin in the resins is preferably 5% by mass or less, more preferably 3% mass or less, and still more preferably 1% by mass or less, and particularly preferably, the acid type resin is not contained. In addition, the expression of “being substantially composed of only a base type resin” preferably means that the content of the resins other than the base type resin in the resins is preferably 5% by mass or less, more preferably 3% mass or less, and still more preferably 1% by mass or less, and particularly preferably, the base type resin is not contained.

Here, the acid type resin represents that the amount of the acid groups is higher than that of the basic group. For the acid type resin, when the sum of the amount of the acid groups and the basic groups in the resin is defined as 100% by mole, the amount of the acid groups preferably accounts for 70% by mole or more, and the resin is more preferably substantially composed of only the acid groups. As the acid group contained in the acid type resin, a carboxyl group is preferable. The acid value of the acid type resin is preferably 40 mgKOH/g to 105 mgKOH/g, more preferably 50 mgKOH/g to 105 mgKOH/g, and still more preferably 60 mgKOH/g to 105 mgKOH/g.

Furthermore, the base type resin represents that the amount of the base groups is higher than that of the basic group. For the base type resin, when the sum of the amount of the acid groups and the basic groups in the resin is defined as 100% by mole, the amount of the basic groups preferably accounts for 50% by mole or more. As the basic group contained in the base type resin, an amine is preferable.

Examples of the resin that can be used as a dispersing agent include polymer dispersing agents [for example, polyamide amines and salts thereof, polycarboxylic acids and salts thereof, high-molecular-weight unsaturated acid esters, modified polyurethanes, modified polyesters, modified poly(meth)acrylates, (meth)acrylic copolymers, and naphthalene sulfonic acid formalin condensates], polyoxyethylene alkyl phosphates, polyoxyethylene alkyl amines, alkanol amines, and pigment derivatives.

According to the structure, the polymer dispersing agents can further be classified into linear polymers, terminal-modified polymers, graft type polymers, and block type polymers.

The polymer dispersing agent acts to be adsorbed by the surface of a pigment to prevent re-aggregation. Accordingly, examples of the preferred structures of the polymer dispersing agent include a terminal-modified polymer having a moiety anchored to a pigment surface, a graft type polymer, and a block type polymer.

Examples of a terminal-modified polymer having a moiety anchored to the pigment surface include a polymer having a phosphoric acid group in the terminal as described in JP1991-112992A (JP-H03-112992A), JP2003-533455A, and the like, a polymer having a sulfonic acid group in the terminal as described in JP2002-273191A, a polymer having a partial skeleton or a heterocycle of an organic colorant as described in JP1997-77994A (JP-H09-77994A), and the like. Moreover, a polymer obtained by introducing two or more moieties (acid groups, basic groups, partial skeletons of an organic colorant, heterocycles, or the like) anchored to the pigment surface into a polymer terminal as described in JP2007-277514A is also preferable since this polymer is excellent in dispersion stability.

Examples of the graft type polymers having a moiety anchored to the pigment surface include polyester-based dispersing agent and the like, and specific examples thereof include a product of a reaction between a poly(lower alkyleneimine) and a polyester, which is described in JP 1979-37082A (JP-S54-37082A), JP 1996-507960A (JP-H08-507960A), JP2009-258668A, and the like, a product of a reaction between a polyallylamine and a polyester, which is described in JP1997-169821A (JP-H09-169821A) and the like, a copolymer of a macromonomer and a nitrogen atom monomer, which is described in JP1998-339949A (JP-H10-339949A), JP2004-37986A, WO2010/110491A, and the like, a graft type polymer having a partial skeleton or a heterocycle of an organic colorant, which is described in JP2003-238837A, JP2008-9426A, JP2008-81732A, and the like, and a copolymer of a macromonomer and an acid group-containing monomer, which is described in JP2010-106268A, and the like. In particular, from the viewpoint of dispersibility of a pigment dispersion, dispersion stability, and developability of which a coloring composition using the pigment dispersion exhibits, an amphoteric dispersion resin having basic and acid groups, which is described in JP2009-203462A, is particularly preferable.

As the macromonomer used in production of a graft type polymer having a moiety anchored to the pigment surface by radical polymerization, known macromonomers can be used. Examples thereof include macromonomers AA-6 (polymethyl methacrylate having a methacryloyl group as a terminal group), AS-6 (polystyrene having a methacryloyl group as a terminal group), AN-6S (a copolymer of styrene and acrylonitrile which has a methacryloyl group as a terminal group), and AB-6 (polybutyl acrylate having a methacryloyl group as a terminal group) manufactured by TOAGOSEI CO., LTD.; PLACCEL FM 5 (a product obtained by adding 5 molar equivalents of s-caprolactone to 2-hydroxyethyl methacrylate) and FA10L (a product obtained by adding 10 molar equivalents of ε-caprolactone to 2-hydroxyethyl acrylate) manufactured by DAICEL CORPORATION; a polyester-based macromonomer described in JP1990-272009A (JP-H02-272009A), and the like. Among these, from the viewpoint of dispersibility of the pigment dispersion, dispersion stability, and the developability of which the coloring composition using the pigment dispersion exhibits, the polyester-based macromonomer excellent in flexibility and solvent compatibility is particularly preferable. Further, a polyester-based macromonomer represented by the polyester-based macromonomer described in JP1990-272009A (JP-H02-272009A) is most preferable.

Preferable examples of the block type polymer having a moiety anchored to a pigment surface include the block type polymers described in JP2003-49110A, JP2009-52010A, and the like.

The pigment dispersing agents which can be used in the present invention can be obtained in the form of commercially available products, and specific examples thereof include “DA-7301” manufactured by Kusumoto Chemicals, Ltd., “DISPERBYK-101 (polyamidamine phosphate), 107 (carboxylic ester), 110 (copolymer including an acid group), 111 (phosphoric acid-based dispersing agent), 130 (polyamide), 161, 162, 163, 164, 165, 166, and 170 (polymeric copolymer)”, and “BYK-P104 and P105 (high-molecular-weight unsaturated polycarboxylic acid)”, manufactured by BYK-Chemie, “EFKA 4047, 4050 to 4010 to 4165 (polyurethane-based dispersing agent), EFKA 4330 to 4340 (block copolymer), 4400 to 4402 (modified polyacrylate), 5010 (polyesteramide), 5765 (high-molecular-weight polycarboxylate), 6220 (aliphatic polyester), 6745 (phthalocyanine derivative), and 6750 (azo pigment derivative)” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E, and No. 300 (acrylic copolymer)”, manufactured by KYOEISHA CHEMICAL CO., LTD., “DISPARLON KS-860, 873SN, 874, #2150 (aliphatic polyvalent carboxylic acid), #7004 (polyether ester), DA-703-50, DA-705, and DA-725”, manufactured by Kusumoto Chemicals, Ltd., “DEMOL RN, N (naphthalene sulfonate formalin polycondensates), MS, C, and SN—B (aromatic sulfonate formalin polycondensates)”, “HOMOGENOL L-18 (polymeric polycarboxylic acid)”, “EMULGEN 920, 930, 935, and 985 (polyoxyethylene nonyl phenyl ether)”, and “ACETAMINE 86 (stearylamine acetate)”, manufactured by Kao Corporation, “SOLSPERSE 5000 (phthalocyanine derivative), 22000 (azo pigment derivative), 13240 (polyesteramine), 3000, 17000, and 27000 (polymers having a functional portion in the terminal portion), and 24000, 28000, 32000, and 38500 (graft type polymers)”, manufactured by Lubrizol Japan Ltd., “NIKKOL T106 (polyoxyethylene sorbitan monooleate) and MYS-IEX (polyoxyethylene monostearate)” manufactured by NIKKO CHEMICALS Co., Ltd., “HINOACT T-8000E” and the like manufactured by Kawaken Fine Chemicals Co., Ltd., “ORGANOSILOXANE POLYMER KP341” manufactured by Shin-Etsu Chemical Co., Ltd., cationic surfactants such as “W001” manufactured by Yusho Co., Ltd., nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester, and anionic surfactants such as “W004, W005, and W017”, “EFKA-46, EFKA-47, EFKA-47EA, EFKA POLYMER 100, EFKA POLYMER 400, EFKA POLYMER 401, and EFKA POLYMER 450” manufactured by MORISHITA SANGYO CO., LTd., polymer dispersing agents such as “DISPERSE AID 6, DISPERSE AID 8, DISPERSE AID 15, and DISPERSE AID 9100” manufactured by SAN NOPCO Ltd., “ADEKA PLUORNIC L31, F38, L42, L44, L61, L64, F68, L72, P95, F77, P84, F87, P94, L101, P103, F108, L121, and P-123” manufactured by ADEKA Corporation, and “IONET (trade name)S-20” manufactured by Sanyo Chemical Industries, Ltd.

In addition, acrylic-based FFS-6752, acrylate-based FFS-187, ACRYCURE RD-F8, or CYCLOMER P can also be used. Further, the following resins can also be used. (The numeral values also described in the respective structural units (numeral values also described in the repeating units of the main chain) are the contents [unit: % by mass] of the respective structural units. The numeral values also described in the repeating moieties of the side chain represent the repetition number of the repeating moieties.)

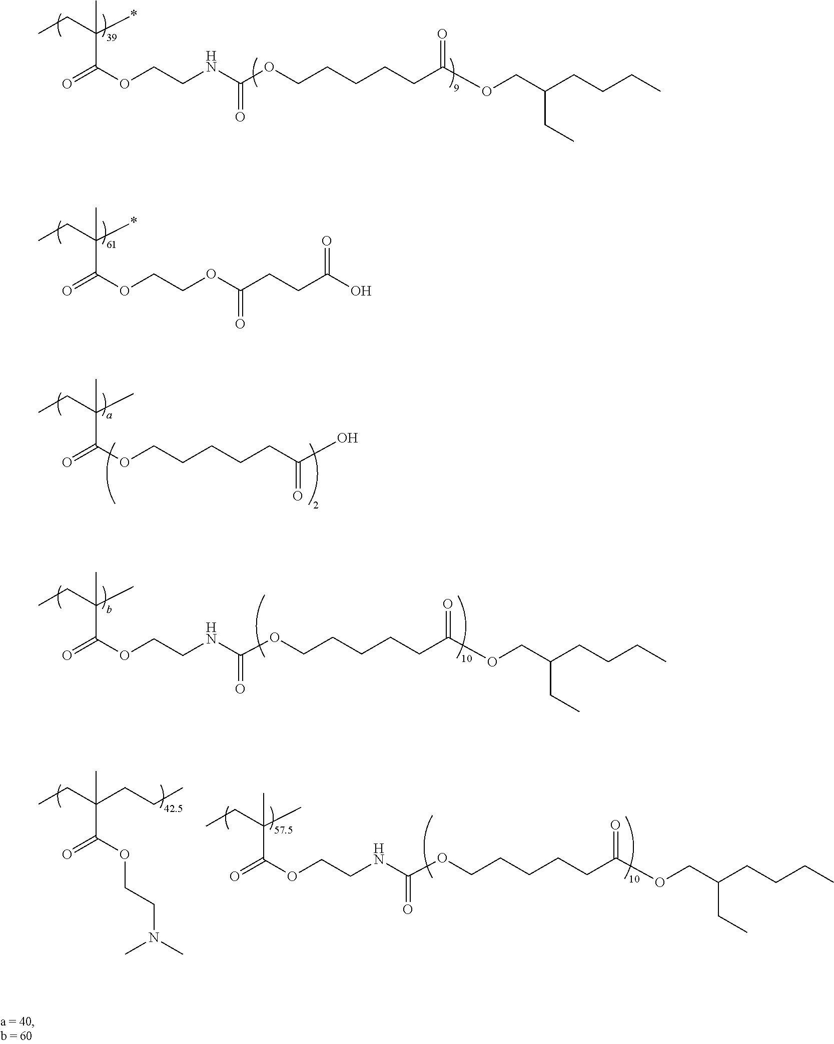

Furthermore, a block copolymer obtained by radical polymerizing a polymerizable unsaturated compound in the presence of a reversible addition-fragmentation chain transfer agent (RAFT agent) such as a dithiocarbonyl compound, and a radical initiator, or a copolymer having a narrow molecular weight distribution may also be used as the dispersing agent. Specific examples of such resins may include resins described in paragraph Nos. 0053 to 0129 of JP2008-242081A, paragraph Nos. 0049 to 0117 of JP2008-176218A, and the like, the contents of which will be incorporated herein by reference. In addition, the block copolymer or the copolymer having a narrow molecular weight distribution may also be used as an alkali-soluble resin.

These resins may be used singly or in combination of two or more kinds thereof. In the present invention, it is preferable to use a pigment derivative in combination with a polymer dispersing agent.

In the case where the coloring composition of the present invention contains other resins (dispersing agents), the total content of the other resins (dispersing agents) may be 1 part by mass to 80 parts by mass, 5 parts by mass to 70 parts by mass, or 10 parts by mass to 60 parts by mass, with respect to 100 parts by mass of the colorant.

In the case where the coloring composition of the present invention substantially does not other resins (dispersing agents), the content of the other resins (dispersing agents) may be 5 parts by mass or less, 1 part by mass or less, or 0 part by mass, with respect to 100 parts by mass of the colorant.

The coloring composition of the present invention may include one kind or two or more kinds of other resins (dispersing agents). In the case where two or more kinds of the other resins are included, the total amount thereof is preferably within the range.

<<Pigment Derivative>>

The coloring composition of the present invention may contain a pigment derivative. The pigment derivative is a compound which has a structure in which a portion of an organic pigment is substituted with an acidic group, a basic group, or a phthalimidomethyl group. From the point of view of the dispersibility and dispersion stability of the pigment, a pigment derivative having an acidic group or a basic group is preferable, and a pigment derivative having a basic group is particularly preferable. Further, as a combination of the above-mentioned resin (dispersing agent) and the pigment derivative, a combination in which the resin is an acid type resin having an acid group and the pigment derivative has a basic group. Accordingly, the viscosity stability of the coloring composition can further be improved. In addition, the generation of acicular crystals during heating at a high temperature can be inhibited.

Examples of the organic pigment for constituting the pigment derivative include a diketopyrrolopyrrole-based pigment, an azo-based pigment, a phthalocyanine-based pigment, an anthraquinone-based pigment, a quinacridone-based pigment, a dioxazine-based pigment, a perinone-based pigment, a perylene-based pigment, a thioindigo-based pigment, an isoindoline-based pigment, an isoindolinone-based pigment, a quinophthalone-based pigment, a threne-based pigment, and a metal complex-based pigment.

In addition, the acidic group contained in the pigment derivative is preferably a sulfonic acid group, a carboxylic acid group, or a quaternary ammonium salt group thereof, more preferably a carboxylic acid group or a sulfonic acid group, and particularly preferably a sulfonic acid group. The basic group contained in the pigment derivative is preferably an amino group and particularly preferably a tertiary amino group.

As the pigment derivative, particularly a quinoline-based, a benzimidazolone-based, or isoindoline-based pigment derivative is preferable, and a quinoline-based or benzimidazolone-based pigment derivative is more preferable. In particular, the pigment derivative having the following structure is preferable.

A-BC-D-E)ₜ (P)

In General Formula (P), A represents a partial structure, selected from the following General Formulae (PA-1) to (PA-3). B represents a single bond or a (t+1)-valent linking group. C represents a single bond, —NH—, —CONH—, —CO₂—, —SO₂NH—, —O—, —S—, or —SO₂—. D represents a single bond, an alkylene group, a cycloalkylene group, or an arylene group. E represents —SO₃H, —SO₃M (M represents an alkali metal atom), —CO₂H, or N(Rpa)(Rpb). Rpa and Rpb each independently represent an alkyl group or an aryl group and Rpa and Rpb may be linked with each other to form a ring. t represents an integer of 1 to 5.

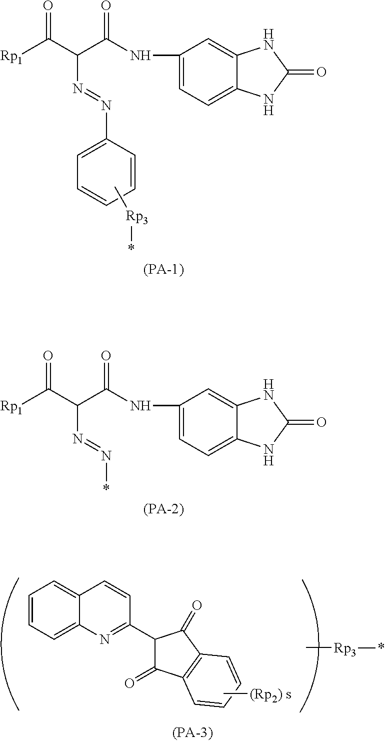

In General Formulae (PA-1) and (PA-2), Rp¹ represents an alkyl group having 1 to 5 carbon atoms or an aryl group. In General Formula (PA-3), Rp² represents a hydrogen atom, a halogen atom, an alkyl group, or a hydroxyl group. s represents an integer of 1 to 4. In the case where s is 2 or more, the plurality of Rp2's may be the same as or different from each other. In General Formula (PA-1) and General Formula (PA-3), Rp³ represents a single bond, —NH—, —CONH—, —CO₂—, —SO₂NH—, —O—, —S—, or —SO₂—. * represents a linking moiety with B.

In General Formula (P), Rp¹ is particularly preferably a methyl group or a phenyl group, and most preferably a methyl group. In General Formula (PA-3), Rp² is preferably a hydrogen atom or a halogen atom, and most preferably a hydrogen atom or a chlorine atom.

In General Formula (P), examples of the (t+1)-valent linking group represented by B include an alkylene group, a cycloalkylene group, an arylene group, and a heteroarylene group. Among these, a linking group represented by the following Structural Formulae (PA-4) to (PA-9) is particularly preferable.

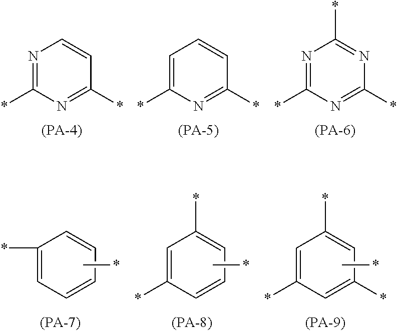

In Structural Formulae (PA-4) to (PA-9), a pigment derivative which has a linking group represented by Structural Formulae (PA-5) or (PA-8) as B is particularly preferable due to superior dispersibility.

In General Formula (P), examples of the alkylene group, the cycloalkylene group, and the arylene group, represented by D, include methylene, ethylene, propylene, butylene, pentylene, hexylene, decylene, cyclopropylene, cyclobutylene, cyclopentylene, cyclohexylene, cyclooctylene, cyclodecylene, phenylene, and naphthylene. Among these, D is particularly preferably an alkylene group, and more preferably an alkylene group having 1 to 5 carbon atoms.

In General Formula (P), in the case where E represents —N(Rpa)(Rpb), examples of the alkyl group and the aryl group in Rpa and Rpb include a methyl group, an ethyl group, a propyl group, an isopropyl group, a butyl group, a sec-butyl group, a tert-butyl group, a pentyl group, an isopentyl group, a neopentyl group, a hexyl group, an octyl group, a decyl group, a cyclopropyl group, a cyclobutyl group, a cyclopentyl group, a cyclohexyl group, a cyclooctyl group, a cyclodecyl group, a phenyl group, and a naphthyl group. Rpa and Rpb are particularly preferably an alkyl group, and most preferably an alkyl group having 1 to 5 carbon atoms. In General Formula (P), t is preferably 1 or 2.

Specific examples of the pigment derivative are shown below, but the present invention is not limited thereto.

For other pigment derivatives, reference may be made to the description in paragraphs 0162 to 0183 of JP2011-252065A, the contents of which will be incorporated herein by reference.

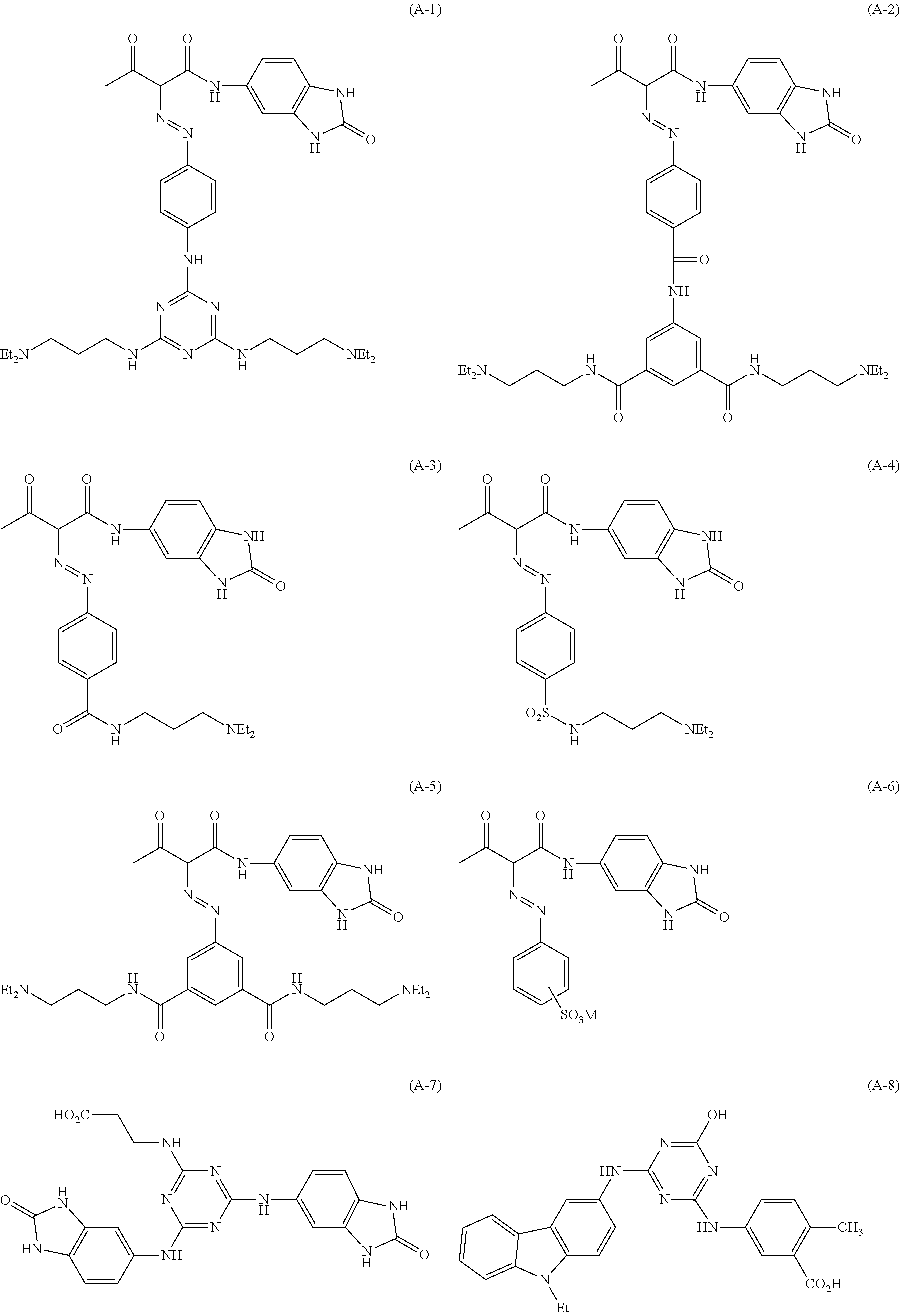

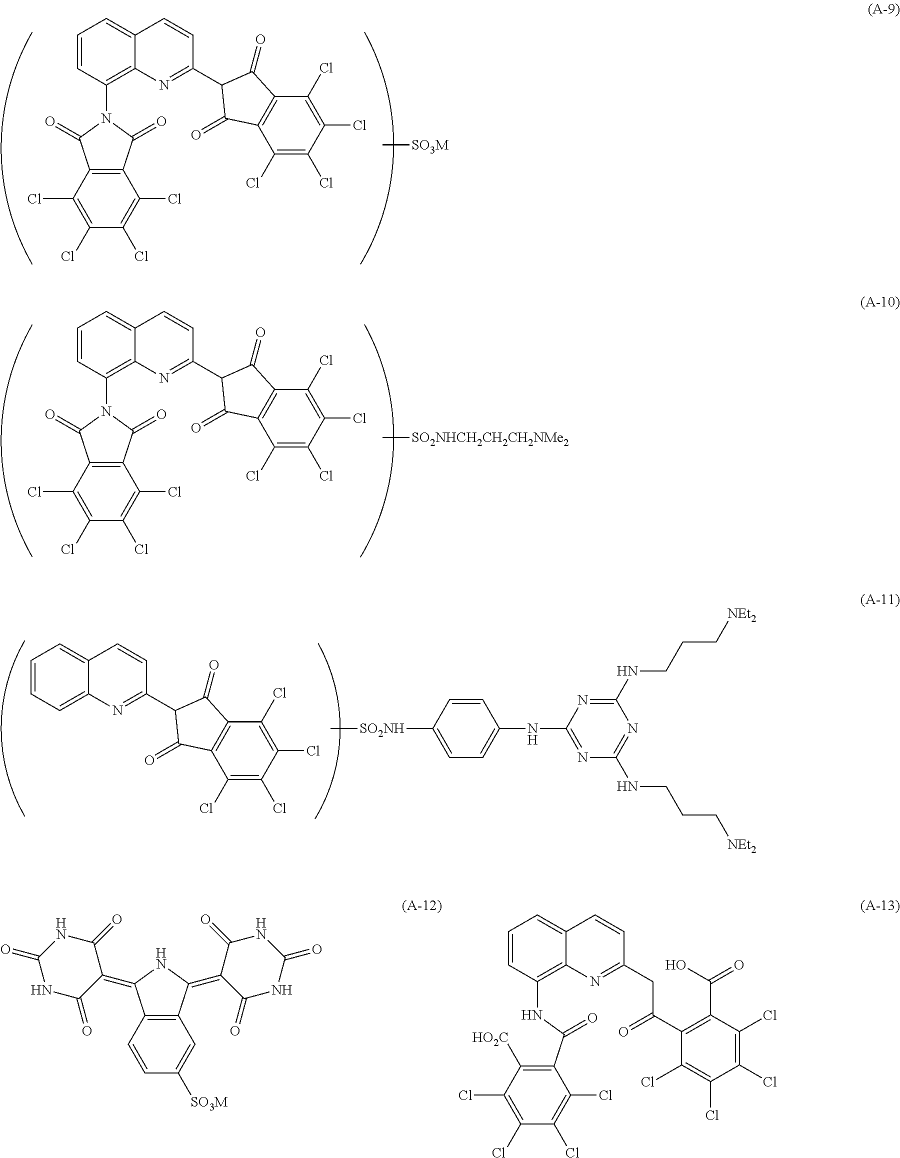

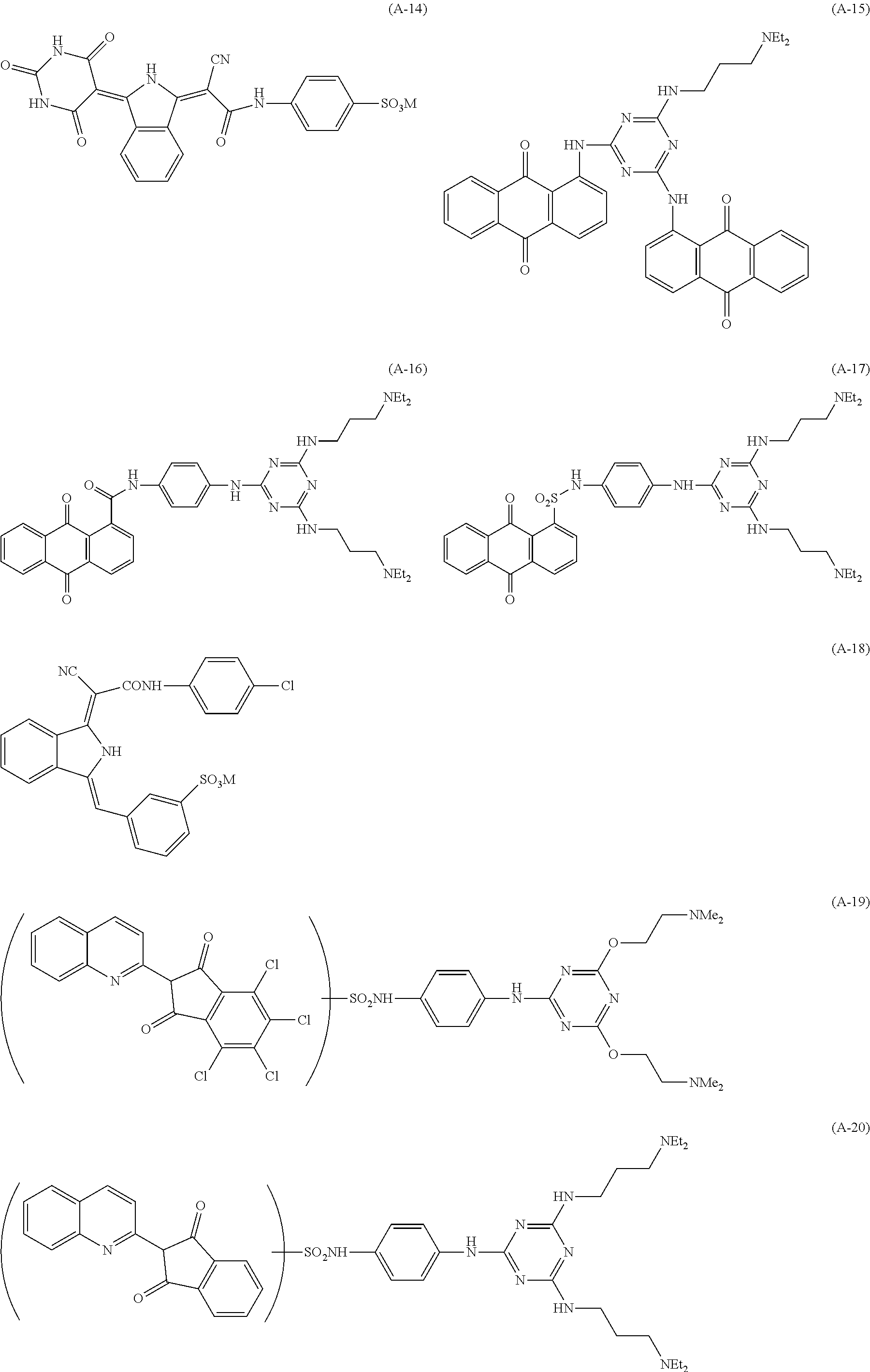

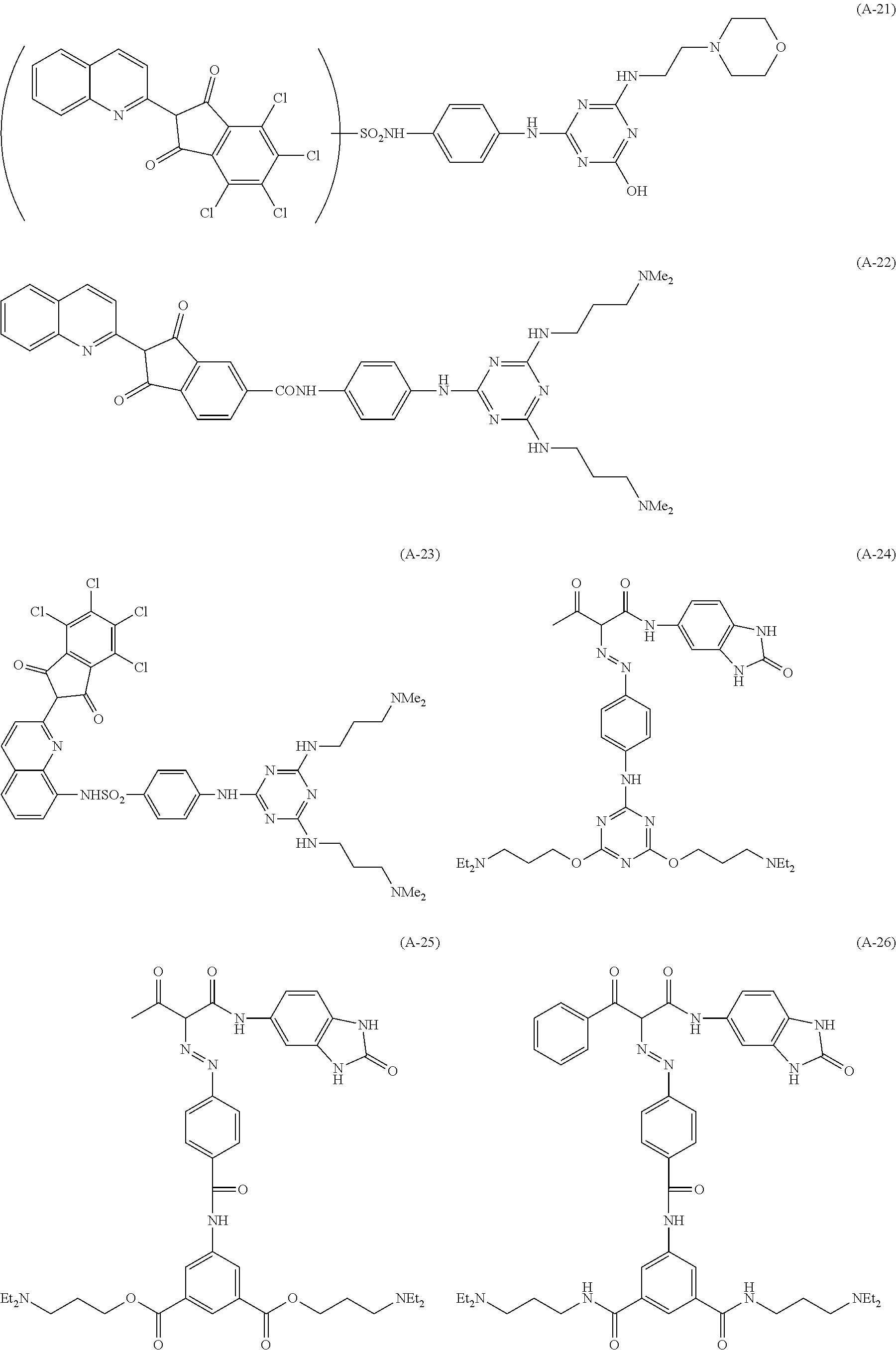

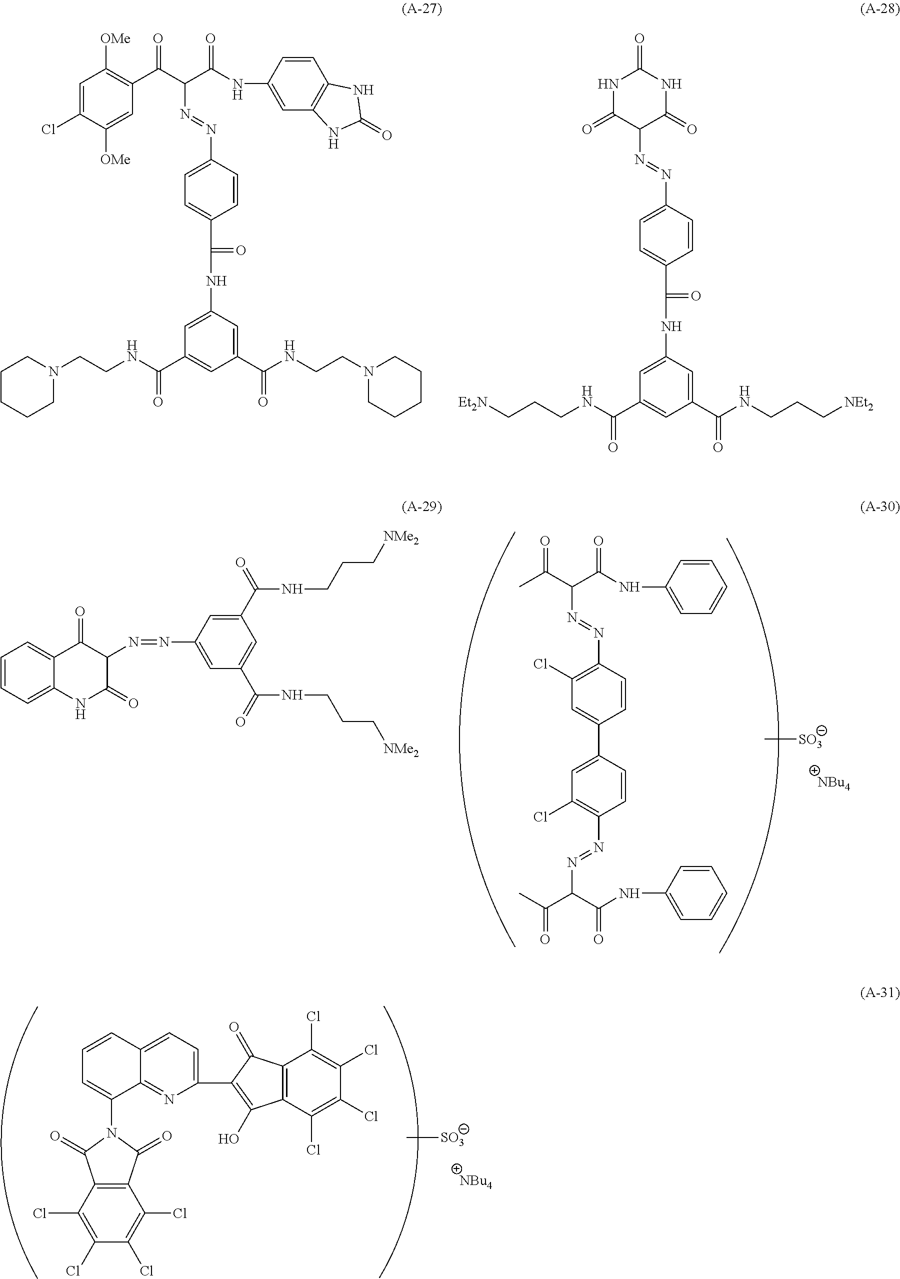

In the case where the coloring composition of the present invention contains a pigment derivative, the content of the pigment derivative is preferably 1% by mass to 30% by mass, and more preferably 3% by mass to 20% by mass, with respect to the total mass of the colorant. The pigment derivatives may be used singly or in combination of two or more kinds thereof. In the case where two or more kinds of the pigment derivatives, the total amount thereof is preferably within the range.

<<Curable Compound>>

It is preferable that the coloring composition of the present invention contains a curable compound. As the curable compound, known polymerizable compounds which can be crosslinked by a radical, an acid, or heat can be used. Examples thereof include polymerizable compounds having an ethylenically unsaturated bond, a cyclic ether (epoxy or oxetane), methylol, or the like. In the case where a pattern is formed by a dry etching method, a compound having an epoxy group is preferably used.

In the case where the coloring composition of the present invention contains a curable compound, the content of the curable compound is preferably 1% by mass to 30% by mass, more preferably 1% by mass to 20% by mass, and particularly preferably 1% by mass to 15% by mass. The coloring composition of the present invention may contain one kind or two or more kinds of the curable compound. In the case where the coloring composition includes two or more kinds of the curable compounds, the total amount thereof is preferably within the range.

<<<Compound Having Epoxy Group>>>

In the present invention, a compound having an epoxy group can be preferably used as the curable compound. As the compound having an epoxy group, one having two or more epoxy groups within one molecule is preferable. By using the compound having two or more epoxy groups within one molecule, the effects of the present invention can be more effectively accomplished. The number of the epoxy groups within one molecule is preferably 2 to 10, more preferably 2 to 5, and particularly preferably 3.

As the compound having an epoxy group in the present invention, one having a structure in which two benzene rings are linked via a hydrocarbon group is preferably used. As the hydrocarbon group, an alkylene group having 1 to 6 carbon atoms is preferable.

Further, as the epoxy group, one linked via a linking group is preferably used. Examples of the linking group include groups including at least one selected from an alkylene group, an arylene group, —O—, a structure represented by —NR′— (R′ represents a hydrogen atom, an alkyl group which may have a substituent, or an aryl group which may have a substituent, and preferably a hydrogen atom), —SO₂—, —CO—, —O—, and —S—.

The compound having such a structure causes an interaction between the halogenated zinc phthalimide pigment and the compound having an epoxy group, and is thus likely to be present in the vicinity of the halogenated zinc phthalimide pigment. As a result, the reaction of the compound having an epoxy group is likely to occur in the vicinity of the halogenated zinc phthalimide pigment, sublimation or heat transfer of the halogenated zinc phthalimide pigment can be efficiently inhibited, and thus, the generation of acicular crystals during heating at a high temperature can be more effectively inhibited.

The epoxy equivalents (=the molecular weight of the compound having an epoxy group/the number of epoxy groups) of the compound having an epoxy group is preferably 500 g/eq or less, more preferably 100 g/eq to 400 g/eq, and still more preferably 100 g/eq to 300 g/eq. By setting the upper limit of the epoxy equivalents of the compound having an epoxy group to 500 g/eq or less, the effects are obtained. Further, it is preferable to set the lower limit of the epoxy equivalents of the compound having an epoxy group to 100 g/eq or more in view of stability in practical use.

The compound having an epoxy group may be either a low-molecular-weight compound (for example, a molecular weight of less than 2,000, and further a molecular weight of less than 1,000) or a high-molecular-weight compound (macromolecule) (for example, a molecular weight of 1,000 or more, and in the case of a polymer, a weight-average molecular weight of 1,000 or more). The weight-average molecular weight of the compound having an epoxy group is preferably 200 to 100,000, and more preferably 500 to 10,000.

As the compound having an epoxy group, for example, a compound represented by the following General Formula (EP1) can be used.

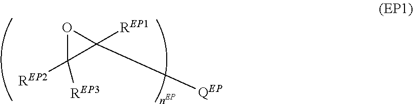

In Formula (EP1), R^{EP1} to R^{EP3} each represent a hydrogen atom, a halogen atom, or an alkyl group, in which the alkyl group may have a cyclic structure or may have a substituent. R^{EP1} and R^{EP2}, or R^{EP2} and R^{EP3} may be bonded with each other to form a cyclic structure. Examples of the substituent which may be contained in the alkyl group include a hydroxyl group, a cyano group, an alkoxy group, an alkylcarbonyl group, an alkoxycarbonyl group, an alkylcarbonyloxy group, an alkylthio group, an alkylsulfone group, an alkylsulfonyl group, an alkylamino group, and an alkylamide group.

Q^{EP} represents a single bond or an n^{EP}-valent organic group. R^{EP1} to R^{EP3} may also be bonded to Q^{EP} to form a cyclic structure.

n^{EP} represents an integer of 2 or more, preferably 2 to 10, and more preferably 2 to 6. In the case where Q^{EP} is a single bond, n^{EP} is 2.

In the case where Q^{EP} is an n^{EP}-valent organic group, it is preferably a chained or cyclic n^{EP}-valent saturated hydrocarbon group (preferably having 2 to 20 carbon atoms); an n^{EP}-valent aromatic ring group (preferably having 6 to 30 carbon atoms); and an (n^{EP})-valent organic group having a structure in which chained or cyclic saturated hydrocarbon or aromatic hydrocarbon is linked to a divalent linking group such as an ether group, an ester group, an amide group, a sulfonamide group, and an alkylene group (preferably having 1 to 4 carbon atoms, and more preferably a methylene group) linked to a trivalent linking group such as —N(−)₂ or linked to any combination of these groups.

Specific examples thereof are shown below, but the present invention is not limited thereto.

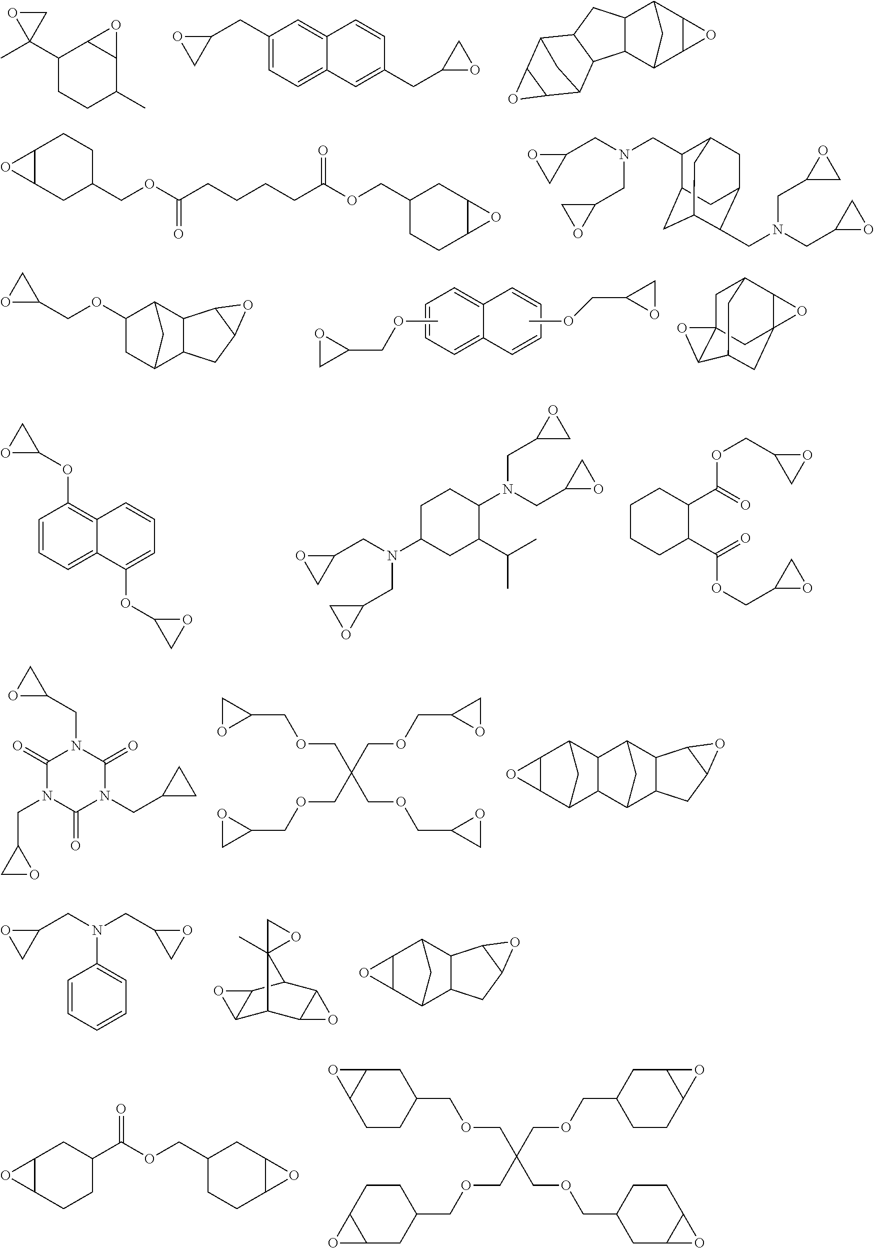

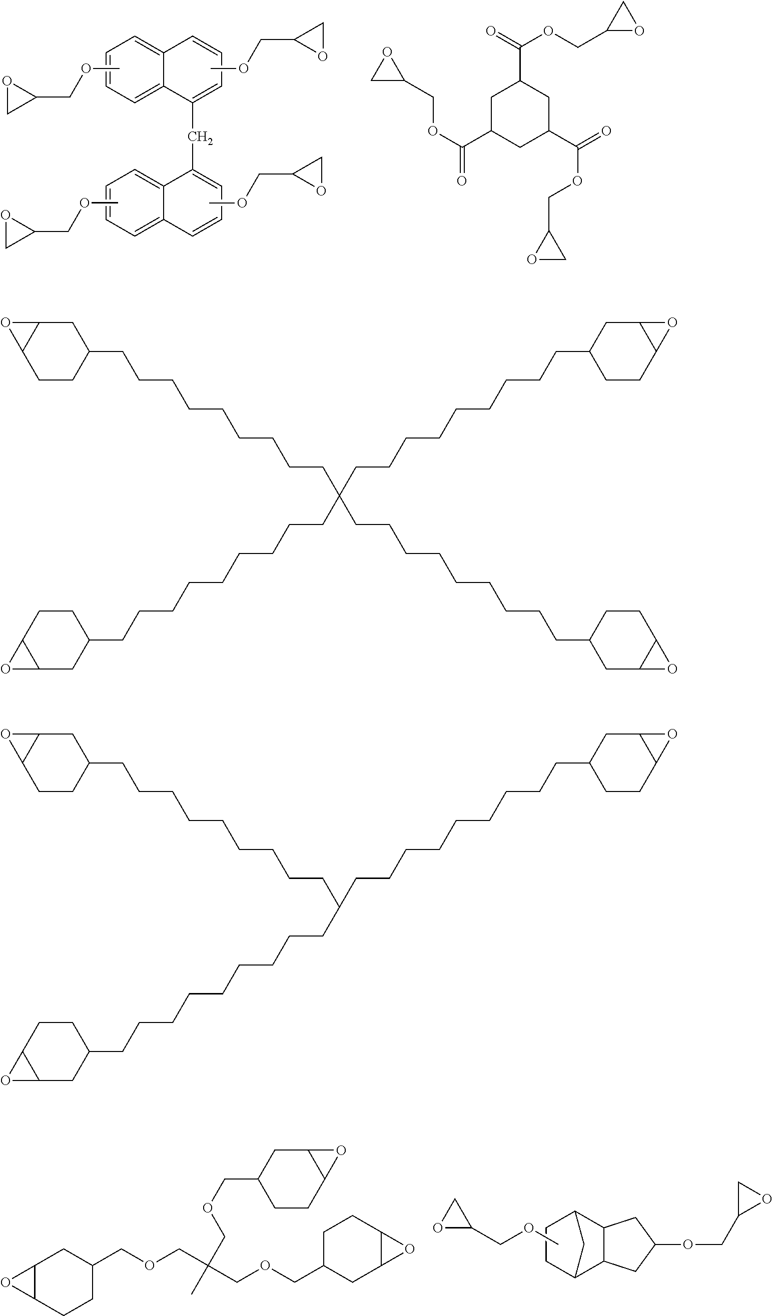

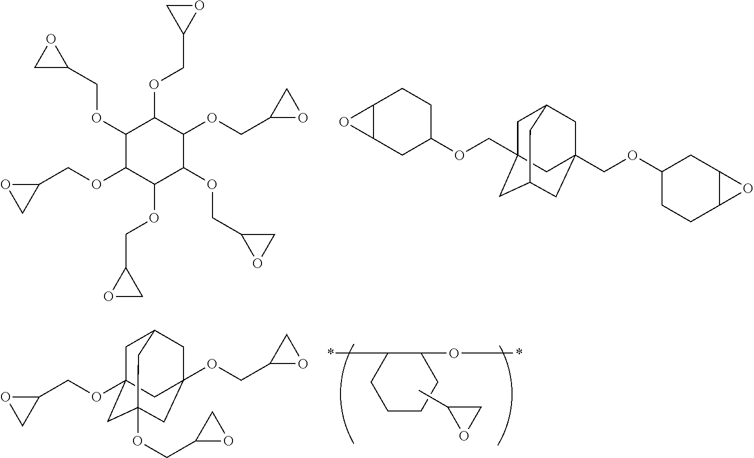

An oligomer or a polymer, having an epoxy group in the side chain, can also be preferably used as the compound having an epoxy group. Examples of such a compound include a bisphenol A type epoxy resin, a bisphenol F type epoxy resin, a phenol novolac type epoxy resin, a cresol novolac type epoxy resin, and an aliphatic epoxy resin.

As these compounds, commercially available products may be used or the compounds may also be obtained by introducing an epoxy group into the side chain of a polymer.

As the commercially available product, examples of the bisphenol A epoxy resin include JER827, JER828, JER834, JER1001, JER1002, JER1003, JER1055, JER1007, JER1009, and JER1010 (all manufactured by Japan Epoxy Resin Co., Ltd.), EPICLON860, EPICLON1050, EPICLON1051, and EPICLON1055 (all manufactured by DIC Corporation); examples of the bisphenol F epoxy resin include JER806, JER807, JER4004, JER4005, JER4007, and JER4010 (all manufactured by Japan Epoxy Resin Co., Ltd.), EPICLON830 and EPICLON835 (all manufactured by DIC Corporation), LCE-21 and RE-602S (all manufactured by Nippon Kayaku Co., Ltd.); examples of the phenol novolac type epoxy resin include JER152, JER154, JER157S70, and JER157S65 (all manufactured by Japan Epoxy Resin Co., Ltd.), EPICLON N-740, EPICLON N-770, and EPICLON N-775 (all manufactured by DIC Corporation); examples of the cresol novolac type epoxy resin include EPICLON N-660, EPICLON N-665, EPICLON N-670, EPICLON N-673, EPICLON N-680, EPICLON N-690, and EPICLON N-695 (all manufactured by DIC Corporation), EOCN-1020 (manufactured by Nippon Kayaku Co., Ltd.); and examples of the aliphatic epoxy resin include ADEKA RESIN EP-4080S, ADEKA RESIN EP-4085S, and ADEKA RESIN EP-4088S (all manufactured by ADEKA Corporation), CELLOXIDE 2021P, CELLOXIDE 2081, CELLOXIDE 2083, CELLOXIDE 2085, EHPE 3150, EPOLEAD PB 3600, and EPOLEAD PB 4700 (all manufactured by Daicel Corporation), Denacol EX-212L, EX-214L, EX-216L, EX-321L, and EX-850L (all manufactured by Nagase ChemteX Corporation). Other examples include ADEKA RESIN EP-4000S, ADEKA RESIN EP-4003S, ADEKA RESIN EP-4010S, and ADEKA RESIN EP-4011S (all manufactured by ADEKA Corporation), NC-2000, NC-3000, NC-7300, XD-1000, EPPN-501, and EPPN-502 (all manufactured by ADEKA Corporation), and JER1031S (manufactured by Japan Epoxy Resin Co., Ltd.).

Furthermore, as the commercially available product of the compound having an epoxy group, JER1031S (manufactured by Mitsubishi Chemical Corporation), JER1032H60 (manufactured by Mitsubishi Chemical Corporation), EPICLON HP-4700 (manufactured by DIC Corporation), and EPICLON N-695 (manufactured by DIC Corporation) can also be preferably used.

In the case of synthesis by introducing an epoxy group into the side chain of a polymer, the introduction reaction can be carried out, using a tertiary amine such as triethylamine and benzylmethylamine, a quaternary ammonium salt such as dodecyltrimethylammonium chloride, tetramethylammonium chloride, and tetraethylammonium chloride, pyridine, or triphenylphosphine as a catalyst in an organic solvent at a reaction temperature of 50° C. to 150° C. for several to several tens of hours. The amount of the alicyclic epoxy unsaturated compounds to be introduced is preferably controlled so that the polymer to be obtained may have an acid value in the range of 5 KOH·mg/g to 200 KOH·mg/g.

While those having a glycidyl group as the epoxy group, such as glycidyl(meth)acrylate and allyl glycidyl ether, may be used as the epoxy unsaturated compound, it is preferable to use an unsaturated compound having an alicyclic epoxy group. Examples of such a compound include the following compounds.

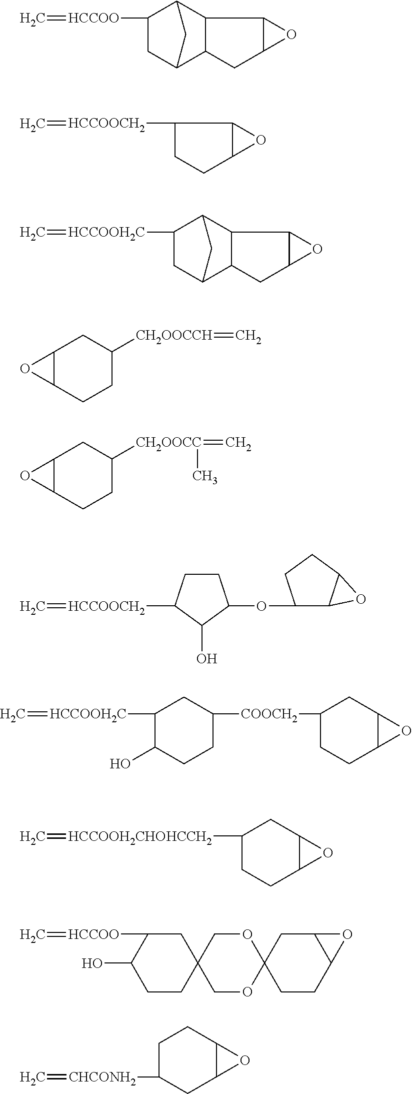

In the present invention, the compounds having an epoxy group may be used singly or in combination of two or more kinds thereof.

<<<Polymerizable Compound Including Ethylenically Unsaturated Bond, Methylol, or the Like.>>>

In the present invention, as a curable compound, a polymerizable compound other than the compound having an epoxy group (hereinafter also referred to as another polymerizable compound) can also be used. As such other polymerizable compound, a compound which has at least one addition-polymerizable ethylene group and has an ethylenically unsaturated group having a boiling point of 100° C. or higher under normal pressure is also preferable. Examples thereof include monofunctional acrylates or methacrylates such as polyethylene glycol mono(meth)acrylate, polypropylene glycol mono(meth)acrylate, and phenoxyethyl (meth)acrylate; ones obtained by adding ethylene oxide or propylene oxide to a polyfunctional alcohol such as polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl) isocyanurate, glycerin, and trimethylolethane, and then (meth)acrylating the resultant; the urethane (meth)acrylates described in JP1973-41708B (JP-S48-41708B), JP1975-6034B (JP-S50-6034B), and JP1976-37193A (JP-S51-37193A); the polyester acrylates described in JP1973-64183A (JP-S48-64183A), JP1974-43191B (JP-S49-43191B), and JP1977-30490B (JP-S52-30490B); a polyfunctional acrylate or methacrylate such as epoxy acrylate as a product of a reaction between an epoxy resin and a (meth)acrylic acid; and a mixture thereof.

Other examples thereof include a polyfunctional (meth)acrylate which is obtained by reacting a polyfunctional carboxylic acid with a compound having a cyclic ether group such as glycidyl (meth)acrylate, and an ethylenically unsaturated group.

Furthermore, the compounds having a fluorene ring and an ethylenically unsaturated, bifunctional or higher group, described in JP2010-160418A, JP2010-129825A, JP4364216B, and the like, or a cardo resin can also be used.

Moreover, as the compound which has a boiling point of 100° C. or higher under normal pressure and has at least one addition-polymerizable ethylenically unsaturated group, the compounds described in paragraph Nos. “0254” to “0257” of JP2008-292970A are also suitable.

In addition to those above, radically polymerizable monomers represented by the following General Formulae (MO-1) to (MO-5) can also be used. Incidentally, in the formulae, in the case where T is an oxyalkylene group, the terminal at a carbon atom side binds to R.

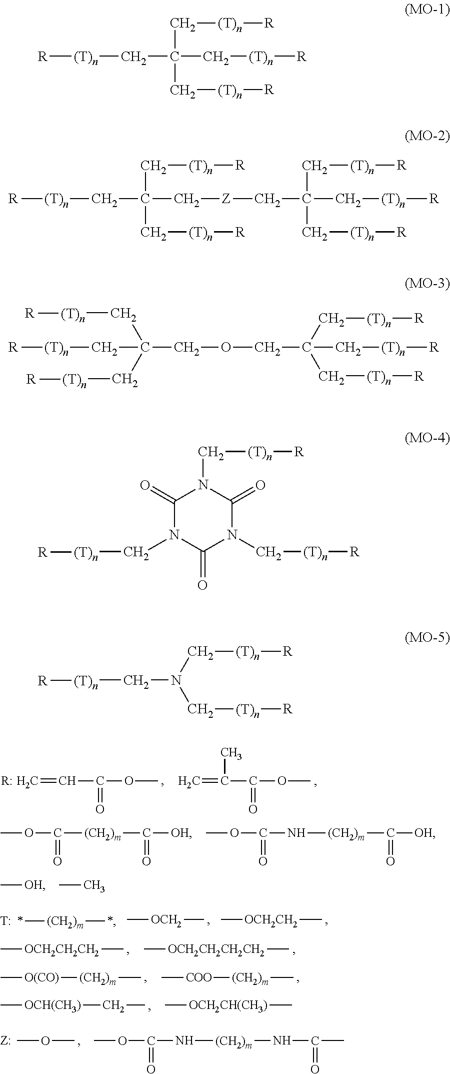

In the general formulae, n is 0 to 14, and m is 1 to 8. A plurality of R's and T's which are present in the same molecule may be the same as or different from each other.

In each of the polymerizable compounds represented by General Formulae (MO-1) to (MO-5), at least one of the plurality of R's represents a group represented by —OC(═O)CH═CH₂ or —OC(═O)C(CH₃)═CH₂.

As specific examples of the polymerizable compounds represented by General Formulae (MO-1) to (MO-5), the compounds described in paragraph Nos. 0248 to 0251 of JP2007-269779A can also be suitably used in the present invention.

In addition, a compound obtained by adding ethylene oxide or propylene oxide to a polyfunctional alcohol, followed by (meth)acrylation, which is described as General Formulae (1) and (2) in JP1998-62986A (JP-H10-62986A) together with the specific examples thereof, can also be used as a polymerizable compound.

Dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd.), and a structure in which ethylene glycol or a propylene glycol residue is interposed between these (meth)acryloyl groups is preferable. Oligomer types of these can also be used.

Other polymerizable compounds may have an acid group such as a carboxyl group, a sulfonic acid group, and a phosphoric acid group as a polyfunctional monomer. If an ethylenic compound has an unreacted carboxyl group as in the case where the ethylene compound is a mixture described above, this compound can be used as is, but if desired, a hydroxyl group of the above ethylenic compound may be reacted with a non-aromatic carboxylic anhydride so as to introduce an acid group. In this case, specific examples of the non-aromatic carboxylic anhydride used include tetrahydrophthalic anhydride, alkylated tetrahydrophthalic anhydride, hexahydrophthalic anhydride, alkylated hexahydrophthalic anhydride, succinic anhydride, and maleic anhydride.

As a polyfunctional monomer having an acid group, a polyfunctional monomer which is an ester obtained between an aliphatic polyhydroxy compound and an unsaturated carboxylic acid and provides an acid group by reacting an unreacted hydroxyl group of the aliphatic polyhydroxy compound with a non-aromatic carboxylic anhydride is preferable, and a monomer in which the aliphatic polyhydroxy compound in the ester is pentaerythritol and/or dipentaerythritol is particularly preferable. Examples of commercially available products thereof include M-510 and M-520, which are polybasic acid-modified acryl oligomers manufactured by TOAGOSEI, CO., LTD.

These monomers may be used singly, but since it is difficult to use a single compound in terms of production, a mixture of two or more kinds of monomers may also be used. In addition, if desired, a polyfunctional monomer not having an acid group and a polyfunctional monomer having an acid group may be used in combination therewith as the monomer.

The acid value of the polyfunctional monomer having an acid group is preferably 0.1 mg KOH/g to 40 mg KOH/g, and particularly preferably 5 mg KOH/g to 30 mg KOH/g. If the acid value of the polyfunctional monomer is too low, the development solubility characteristics deteriorates. If the acid value is too high, difficulty is caused in the production and handleability, hence a photopolymerization performance deteriorates, which leads to deterioration of curability such as surface smoothness of pixels. Therefore, in the case where a combination of two or more kinds of polyfunctional monomers having different acid groups is used, or when a combination of polyfunctional monomers not having an acid group is used, it is preferable to adjust the acid value such that the acid value of all the polyfunctional monomers falls within the above range.

Moreover, in another preferred embodiment, a polyfunctional monomer having a caprolactone structure is contained as such other polymerizable compound.

The polyfunctional monomer having a caprolactone structure is not particularly limited as long as it has a caprolactone structure in a molecule thereof, and examples thereof include ε-caprolactone-modified polyfunctional (meth)acrylates which are obtained by esterifying polyhydric alcohols such as trimethylolethane, ditrimethylolethane, trimethylolpropane, ditrimethylolpropane, pentaerythritol, dipentaerythritol, tripentaerythritol, glycerin, diglycerol, and trimethylolmelamine with (meth)acrylic acid and e-caprolactone. Among these, a polyfunctional monomer having a caprolactone structure represented by the following General Formula (Z-1) is preferable.

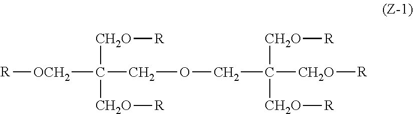

In General Formula (Z-1), all of six R's are a group represented by the following General Formula (Z-2), or one to five of six R's is/are a group represented by the following General Formula (Z-2) and the rest thereof is/are a group represented by the following General Formula (Z-3).

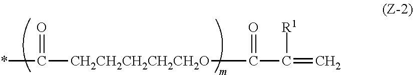

In General Formula (Z-2), R¹ represents a hydrogen atom or a methyl group, m represents 1 or 2, and “*” represents a bonding hand.

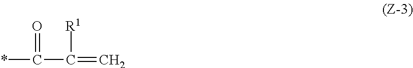

In General Formula (Z-3), R¹ represents a hydrogen atom or a methyl group, and “*” represents a bonding hand.

Such the polyfunctional monomer having a caprolactone structure is commercially available from Nippon Kayaku Co., Ltd., as a KAYARAD DPCA series, and examples thereof include DPCA-20 (a compound in which m is 1, the number of the group represented by Formula (2) is 2, and all of R's are hydrogen atoms in Formulae (1) to (3)), DPCA-30 (a compound in which m is 1, the number of the group represented by Formula (2) is 3, and all of R's are hydrogen atoms in Formulae (1) to (3)), DPCA-60 (a compound in which m is 1, the number of the group represented by Formula (2) is 6, and all of R¹'s are hydrogen atoms in Formulae (1) to (3)), and DPCA-120 (a compound in which m is 2, the number of the group represented by Formula (2) is 6, and all of R's are hydrogen atoms in Formulae (1) to (3)).

The polyfunctional monomer having a caprolactone structure can be used singly or as a mixture of two or more kinds thereof.

Moreover, the other polymerizable compound is preferably at least one kind selected from a group of compounds represented by the following General Formula (Z-4) or (Z-5).

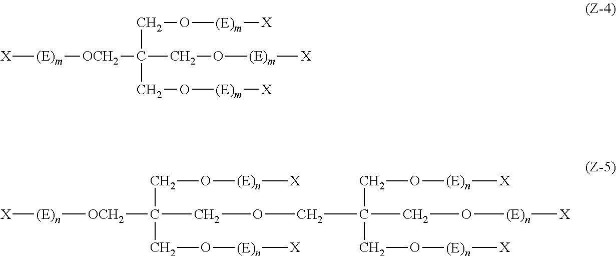

In General Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent an acryloyl group, a methacryloyl group, a hydrogen atom, or a carboxyl group.

In General Formula (Z-4), the sum of the acryloyl group and the methacryloyl group is 3 or 4, m's each independently represent an integer of 0 to 10, and the sum of the respective m's is an integer of 0 to 40. Herein, in the case where the sum of the respective m's is 0, any one of X's is a carboxyl group.

In General Formula (Z-5), the sum of the acryloyl group and the methacryloyl group is 5 or 6, n's each independently represent an integer of 0 to 10, and the sum of the respective n's is an integer of 0 to 60. Herein, in the case where the sum of the respective n's is 0, one of X's is a carboxyl group.

In General Formula (Z-4), m is preferably an integer of 0 to 6, and more preferably an integer of 0 to 4. Further, the sum of the respective m's is preferably an integer of 2 to 40, more preferably an integer of 2 to 16, and particularly preferably an integer of 4 to 8.

In General Formula (Z-5), n is preferably an integer of 0 to 6, and more preferably an integer of 0 to 4.

Further, the sum of the respective n's is preferably an integer of 3 to 60, more preferably an integer of 3 to 24, and particularly preferably an integer of 6 to 12.

In addition, —((CH₂)_{y}CH₂O)— or —((CH₂)_{y}CH(CH₃)O)— in General Formula (Z-4) or (Z-5) is preferably in the form in which the terminal at an oxygen atom side binds to X.

The compound represented by General Formula (Z-4) or (Z-5) may be used singly or in combination of two or more kinds thereof. In particular, a form in which all of six X's in General Formula (Z-5) are acryloyl groups is preferable.

Moreover, the total content of the compound represented by General Formula (Z-4) or (Z-5) in the polymerizable compound is preferably 20% by mass or more, and more preferably 50% by mass or more.

The compound represented by General Formula (Z-4) or (Z-5) can be synthesized by steps known in the related art, which includes a step of binding ethylene oxide or propylene oxide to pentaerythritol or dipentaerythritol by a ring-opening addition reaction to form a ring-opening skeleton, and a step of reacting, for example, (meth)acryloyl chloride to a terminal hydroxyl group of the ring-opening skeleton to introduce a (meth)acryloyl group. Since the respective steps are well-known, a person skilled in the art can easily synthesize the compound represented by General Formula (Z-4) or (Z-5).

Among the compounds represented by General Formula (Z-4) or (Z-5), a pentaerythritol derivative and/or a dipentaerythritol derivative is/are more preferable.

Specific examples of the compounds include compounds represented by the following Formulae (a) to (f) (hereinafter also referred to as “exemplary compounds (a) to (f)”). Among these, the exemplary compounds (a), (b), (e), and (f) are preferable.

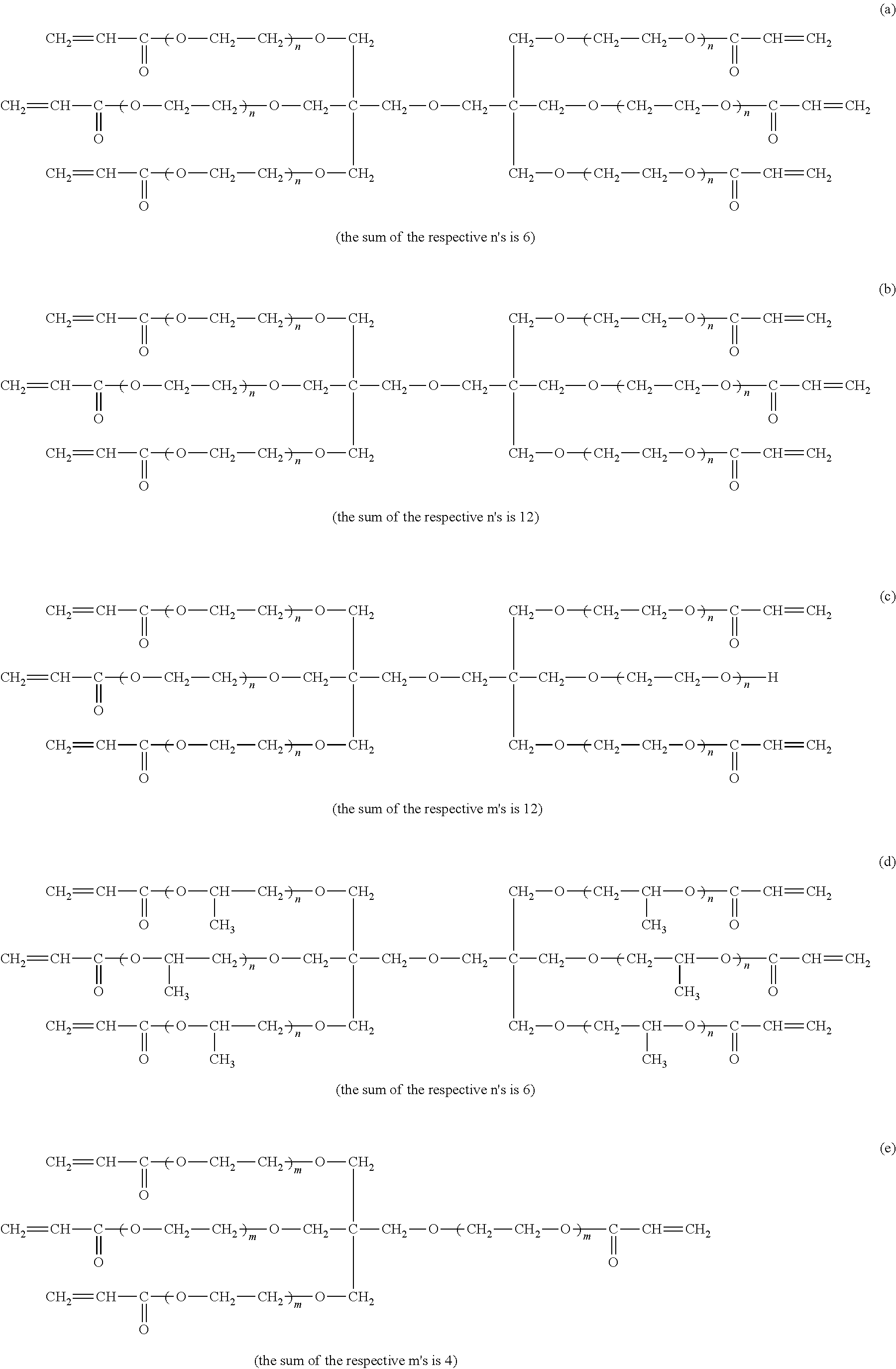

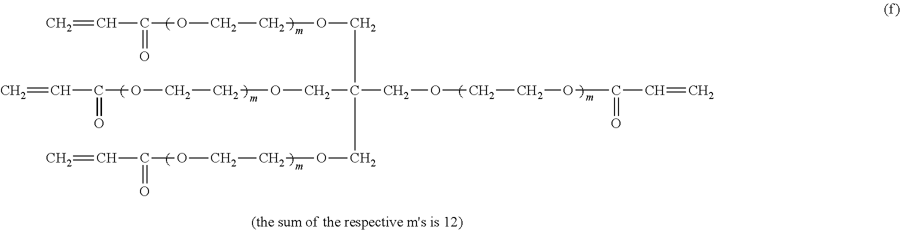

Examples of commercially available products of the polymerizable compounds represented by General Formulae (Z-4) and (Z-5) include SR-494 which is a tetrafunctional acrylate having four ethyleneoxy chains, manufactured by Sartomer, and DPCA-60 which is a hexafunctional acrylate having six pentyleneoxy chains, and TPA-330 which is a trifunctional acrylate having three isobutyleneoxy chains, manufactured by Nippon Kayaku Co., Ltd.

Moreover, as other polymerizable compounds, the urethane acrylates described in JP1973-41708B (JP-S48-41708B), JP1976-37193A (JP-S51-37193A), JP1990-32293B (JP-H02-32293B), and JP1990-16765B (JP-H02-16765B), or urethane compounds having an ethylene oxide-based skeleton described in JP1983-49860B (JP-S58-49860B), JP1981-17654B (JP-S56-17654B), JP1987-39417B (JP-S62-39417B), and JP1987-39418B (JP-S62-39418B) are also preferable. Furthermore, by using addition-polymerizable compounds, which have an amino structure or a sulfide structure in a molecule and are described in JP1988-277653A (JP-S63-277653A), JP1988-260909A (JP-S63-260909A), and JP1989-105238A (JP-H01-105238A), as the polymerizable compounds, a curable composition which is extremely excellent in photosensitization speed can be obtained.

In addition, a compound having an oxetane group can also be used. Examples of the compound having an oxetane group include the compounds described in paragraphs 0134 to 0145 of JP2008-224970A, the contents of which are incorporated herein by reference. Specific examples thereof include ARON OXETANE OXT-121, OXT-221, OX-SQ, and PNOX (all manufactured by Toagosei Co., Ltd.) can be used.

Examples of commercially available products of the polymerizable compounds include urethane oligomers UAS-10 and UAB-140 (manufactured by Sanyo-Kokusaku Pulp, Co., Ltd.), UA-7200 (manufactured by SHIN-NAKAMURA CHEMICAL CO., LTD.), DPHA-40H (manufactured by Nippon Kayaku Co., Ltd.), and UA-306H, UA-306T, UA-306I, AH-600, T-600, and AI-600 (manufactured by KYOEISHA CHEMICAL CO., LTD.).

Details of how to use these polymerizable compounds, such as the structure, whether the polymerizable compounds are used singly or used in combination thereof, and the amount of the polymerizable compounds added, can be arbitrarily set according to the final performance design of the coloring composition. For example, from the viewpoint of sensitivity, a structure in which the content of an unsaturated group per molecule is large is preferable, and in many cases, it is preferable that the polymerizable compound is bifunctional or higher. Moreover, from the viewpoint of enhancing the strength of a cured film formed of the coloring composition, it is preferable that the polymerizable compound is trifunctional or higher. In addition, a method for adjusting both the sensitivity and the strength by using a combination of compounds which differ in the number of functional groups and have different polymerizable groups (for example, an acrylic ester, a methacrylic ester, a styrene-based compound, and a vinylether-based compound) is also effective. Further, it is preferable to use polymerizable compounds which are trifunctional or higher and differ in the length of an ethylene oxide chain in combination with others since the developability of the coloring composition can be adjusted, and excellent pattern formability is obtained.

In addition, from the viewpoints of the compatibility with other components (for example, a photopolymerization initiator, a substance to be dispersed, and an alkali-soluble resin) contained in the coloring composition, and the dispersibility, how to select and use the polymerizable compound is an important factor. For example, if a low-purity compound is used or a combination of two or more kinds thereof is used, the compatibility can be improved in some cases. In addition, from the viewpoint of improving the adhesiveness of the composition to a hard surface of a support or the like, specific structures may be selected in some cases.

<<Organic Solvent>>

It is preferable that the coloring composition of the present invention contains an organic solvent.

The organic solvent is not particularly limited as long as it satisfies the solubility of the respective components or the coatability of the coloring composition, but the organic solvent is preferably selected in consideration of the solubility, the coatability, and the safety of an ultraviolet absorber, a polymerizable compound, a resin (dispersing agent), or the like.

Suitable examples of the organic solvent include esters such as ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl oxyacetate (e.g.: methyl oxyacetate, ethyl oxyacetate, and butyl oxyacetate (e.g.: methyl methoxyacetate, ethyl methoxyacetate, butyl methoxyacetate, methyl ethoxyacetate, and ethyl ethoxyacetate)), alkyl 3-oxypropionate esters (e.g.: methyl 3-oxypropionate and ethyl 3-oxypropionate (e.g.: methyl 3-methoxypropionate, ethyl 3-methoxypropionate, methyl 3-ethoxypropionate, and ethyl 3-ethoxypropionate)), alkyl 2-oxypropionate esters (e.g.: methyl 2-oxypropionate, ethyl 2-oxypropionate, or propyl 2-oxypropionate (e.g.: methyl 2-methoxypropionate, ethyl 2-methoxypropionate, propyl 2-methoxypropionate, methyl 2-ethoxypropionate, or ethyl 2-ethoxypropionate)), methyl 2-oxy-2-methyl propionate and ethyl 2-oxy-2-methyl propionate (e.g.: methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate; ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol methyl ether acetate, propylene glycol ethyl ether acetate, and propylene glycol propyl ether acetate; ketones such as methyl ethyl ketone, cyclohexanone, 2-heptanone, and 3-heptanone; and aromatic hydrocarbons such as toluene and xylene.

From the viewpoints of improvement of the shape of the coated surface, and the like, it is also preferable to mix two or more kinds of these organic solvents. In this case, a mixed solution consisting of two or more kinds selected from the methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butylcarbitol acetate, propylene glycol methyl ether, and propylene glycol methyl ether acetate is particularly preferable. In particular, a mixed solution consisting of cyclohexanone, ethyl 3-ethoxypropionate, and propylene glycol methyl ether acetate is preferable.

From the viewpoint of coatability, the content of the organic solvent in the coloring composition of the present invention is set such that the concentration of the total solid content of the coloring composition becomes preferably 5% by mass to 80% by mass, more preferably 5% by mass to 60% by mass, still more preferably 10% by mass to 50% by mass, and particularly preferably 10% by mass to 40% by mass.

<<Other Components>>

In addition to the respective components as described above, a surfactant, an acid anhydride, a curing agent, a curing catalyst, a photopolymerization initiator, and an alkali-soluble resin can further be blended into the coloring composition of the present invention within a range not diminishing the effects of the present invention.

<<<Surfactant>>>

From the viewpoint of further improving coatability, various surfactants may be added to the coloring composition of the present invention. As the surfactants, it is possible to use various surfactants such as a fluorine-based surfactant, a nonionic surfactant, a cationic surfactant, an anionic surfactant, and a silicone-based surfactant.

In particular, if the coloring composition of the present invention contains a fluorine-based surfactant, liquid characteristics (particularly, fluidity) are further improved when the composition is prepared as a coating liquid, whereby evenness of the coating thickness or liquid saving properties can be further improved.

That is, in the case where a coating liquid obtained by applying the coloring composition containing a fluorine-based surfactant is used to form a film, the surface tension between a surface to be coated and the coating liquid is reduced to improve wettability with respect to the surface to be coated, and enhance coatability with respect to the surface to be coated. Therefore, even in the case where a thin film of about several μm is formed of a small amount of liquid, the coloring composition containing a fluorine-based surfactant is effective in that a film with a uniform thickness which exhibits a small extent of thickness unevenness can be more suitably formed.

The fluorine content in the fluorine-based surfactant is preferably 3% by mass to 40% by mass, more preferably 5% by mass to 30% by mass, and particularly preferably 7% by mass to 25% by mass. The fluorine-based surfactant in which the fluorine content is within this range is effective in terms of the evenness of the thickness of the coated film or liquid saving properties, and the solubility of the surfactant in the coloring composition is also good.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781 (all manufactured by DIC Corporation); FLUORAD FC430, FC431, and FC171 (all manufactured by Sumitomo 3M); and SURFLON S-382, SURFLON SC-101, SURFLON SC-103, SURFLON SC-104, SURFLON SC-105, SURFLON SC1068, SURFLON SC-381, SURFLON SC-383, SURFLON SC-393, and SURFLON KH-40 (all manufactured by ASAHI GLASS Co., Ltd.).

Specific examples of the nonionic surfactant include glycerol, trimethylolpropane, trimethylolethane, and ethoxylate and propoxylate thereof (for example, glycerol propoxylate and glycerin ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters (PLURONIC L10, L31, L61, L62, 10R5, 17R2, and 25R2, and TETRONIC 304, 701, 704, 901, 904, and 150R1 manufactured by BASF), and SOLSEPERSE 20000 (manufactured by Lubrizol Japan Ltd.).

Specific examples of the cationic surfactant include phthalocyanine derivatives (trade name: EFKA-745 manufactured by MORISHITA KAGAKU SANGYO Corporation), organosiloxane polymer KP341 (manufactured by Shin-Etsu Chemical Co., Ltd.), (meth)acrylic acid-based (co)polymer POLYFLOW No. 75, No. 90, and No. 95 (manufactured by KYOEISHA CHEMICAL CO., LTD.), and WOO 1 (manufactured by Yusho Co., Ltd.).

Specific examples of the anionic surfactant include W004, W005, and W017 (manufactured by Yusho Co., Ltd.).

Examples of the silicone-based surfactant include “TORAY SILICONE DC3PA”, “TORAY SILICONE SH7PA”, “TORAY SILICONE DC11PA”, “TORAY SILICONE SH21PA”, “TORAY SILICONE SH28PA”, “TORAY SILICONE SH29PA”, “TORAY SILICONE SH30PA”, and “TORAY SILICONE SH8400”, manufactured by Dow Corning Toray CO., LTD., “TSF-4440”, “TSF-4300”, “TSF-4445”, “TSF-4460”, and “TSF-4452”, manufactured by Momentive Performance Materials Inc., “KP341”, “KF6001”, and “KF6002”, manufactured by Shin-Etsu Chemical Co., Ltd., and “BYK307”, “BYK323”, and “BYK330”, manufactured by BYK-Chemie.

The surfactants may be used singly or in combination of two or more kinds thereof.

The coloring composition of the present invention may or may not contain a surfactant, but in the case where the coloring composition contains a surfactant, the content of the surfactant is preferably 0.001% by mass to 2.0% by mass, and more preferably 0.005% by mass to 1.0% by mass, with respect to the total solid content of the coloring composition.

<<<Acid Anhydride>>>

In the case where the coloring composition of the present invention contains the compound having an epoxy group, it may contain an acid anhydride. By incorporating the acid anhydride into the coloring composition, the crosslinking properties by thermally curing the compound having an epoxy group can be improved.

Examples of the acid anhydride include phthalic anhydride, nadic anhydride, maleic anhydride, and succinic anhydride. Among these, phthalic anhydride is preferable as the acid anhydride from the viewpoint that the effect on pigment dispersion is little.

The content of the acid anhydride in the coloring composition is preferably in the range of 10% by mass to 40% by mass, and more preferably in the range of 15% by mass to 30% by mass, with respect to the mass of the compound having an epoxy group. When the content of acid anhydride is 10% by mass or more, the compound having an epoxy group will have an increased crosslinking density and an increased mechanical strength, whereas when the content is 30% by mass or less, the heat curable components will be suppressed in the coated film, thereby advantageously increasing the concentration of color agents.

<<<Curing Agent>>>

In the case where the coloring composition of the present invention contains the compound having an epoxy group, it may also contain a curing agent. There are a great variety of curing agents, and they largely vary from species to species in properties, the survival time of a mixture of a resin and a curing agent, the viscosity, the curing temperature, the curing time, and the heat generation, so that it is preferable to select an appropriate curing agent taking purpose of use, conditions of use, conditions of working and so forth into consideration. The curing agent is described in detail in “Epoxy Resin” (Shokodo Co., Ltd.), edited by Hiroshi Kakiuchi, Chapter 5. Examples of the curing agent will be enumerated below.

Examples of those demonstrating a catalytic action include a tertiary amines and a boron trifluoride-amine complex; examples of those demonstrating stoichiometric reaction with an epoxy group include a polyamine and an acid anhydride; examples of those curable at normal temperature include diethylenetriamine and a polyamide resin; examples of those curable at middle temperatures include diethylaminopropylamine, and tris(dimethylaminomethyl)phenol; and examples of those curable at high temperatures include phthalic anhydride and meta-phenylenediamine. When classified by the chemical structure, examples of amines include aliphatic polyamines such as diethylenetriamine; aromatic polyamine such as meta-phenylenediamine; tertiary amines such as tris(dimethylaminomethyl)phenol; acid anhydrides such as phthalic anhydride; a polyamide resin, a polysulfide resin, and a boron trifluoride-monoethylamine complex; an initial condensate of a synthetic resin such as a phenol resin, and dicyandiamide.

These curing agents react with an epoxy group under heating, and polymerize the resin, thereby increasing the crosslinking density to perform curing. From the viewpoint of thinning of the film, the amounts of consumption of both of the binder and the curing agent are preferably as small as possible, and in particular, the curing agent is in the amount of 35% by mass or less, preferably 30% by mass or less, and more preferably 25% by mass or less, with respect to the compound having an epoxy group.

<<<Curing Catalyst>>>

In the case where the coloring composition of the present invention contains the compound having an epoxy group, it may also contain a curing catalyst. In order to obtain a composition with a high concentration of colorants, it is effective to employ, in addition to curing by the reaction with the curing agent, a curing mechanism mainly based on a reaction between epoxy groups. For this purpose, a curing catalyst may be used, while abandoning the curing agent. Only a slight amount of addition of the curing catalyst, approximately 1/10 to 1/1,000 on a mass basis, preferably approximately 1/20 to 1/500, and more preferably approximately 1/30 to 1/250, with respect to the epoxy resin with an epoxy equivalent of approximately 150 to 200, will be used to perform curing.

<<<Photopolymerization Initiator>>>

The coloring composition of the present invention may contain a photopolymerization initiator from the viewpoint of further improvement of sensitivity.

The photopolymerization initiator is not particularly limited as long as it has an ability of initiating polymerization of the polymerizable compound, and may be appropriately selected from known photopolymerization initiators. For example, those having photosensitivity to light in the region from ultraviolet to visible are preferred, and the initiator may be an activator that causes a certain action with a photoexcited sensitizer to produce an active radical or an initiator that initiates cationic polymerization according to the kind of the monomer.

For the photopolymerization initiator, for example, reference can be made to the descriptions of paragraph Nos. 0178 to 0226 of JP2013-54080A, the contents of which will be incorporated herein by reference.

The coloring composition of the present invention may not contain a photopolymerization initiator, but the content of the photopolymerization initiator is preferably 0% by mass to 50% by mass, more preferably 0.5% by mass to 30% by mass, and still more preferably 1% by mass to 20% by mass, with respect to the total solid content of the coloring composition of the present invention.

Moreover, in the case where the coloring composition of the present invention is used for a dry etching step, it is preferable that the coloring composition of the present invention substantially does not contain a photopolymerization initiator. In the case where the coloring composition substantially does not contain the photopolymerization initiator, the content of the photopolymerization initiator is preferably 1% by mass or less, more preferably 0.1% by mass or less, and particularly preferably 0% by mass, with respect to the total solid content of the coloring composition of the present invention.

<<<Alkali-Soluble Resin>>>

The coloring composition of the present invention may contain an alkali-soluble resin.

The molecular weight of the alkali-soluble resin is not particularly determined, but Mw is preferably 5,000 to 100,000. Further, Mn is preferably 1,000 to 20,000.

The alkali-soluble resin can be appropriately selected from alkali-soluble resins which are linear organic high molecular-weight polymers and have at least one group enhancing alkali solubility in a molecule (preferably a molecule having an acrylic copolymer or a styrene-based copolymer as a main chain). From the viewpoint of heat resistance, a polyhydroxystyrene-based resin, a polysiloxane-based resin, an acrylic resin, an acrylamide-based resin, and an acryl/acrylamide copolymer resin are preferable, and further, from the viewpoint of controlling developability, an acrylic resin, an acrylamide-based resin, and an acryl/acrylamide copolymer resin are preferable.

For the alkali-soluble resin, reference can be made to the descriptions in paragraphs 0558 to 0571 of JP2012-208494A (“0685” to “0700” of the corresponding US2012/0235099A), the contents of which are incorporated herein by reference.

The coloring composition of the present invention may not contain the alkali-soluble resin, but in the case where it contains the alkali-soluble resin, the content of the alkali-soluble resin is preferably 1% by mass to 15% by mass, more preferably 2% by mass to 12% by mass, and particularly preferably 3% by mass to 10% by mass, with respect to the total solid content of the coloring composition.

The coloring composition of the present invention may include one kind or two or more kinds of alkali-soluble resin. In the case where the composition includes two or more kinds of the alkali-soluble resin, the total amount thereof is preferably within the range.

In addition, various additions, for example, a filler, an adhesion promoter, an antioxidant, an ultraviolet absorbent, an aggregation inhibitor, or the like can be blended into the coloring composition of the present invention, if desired. Examples of these additives include those described in paragraphs 0155 to 0156 of JP2004-295116A.

The coloring composition of the present invention may contain the sensitizer or the light stabilizer described in paragraph 0078 of JP2004-295116A, or the thermal polymerization inhibitor described in paragraph 0081 of the same publication.

<Method for Preparing Coloring Composition>

The coloring composition of the present invention can be prepared by mixing the aforementioned components.

Furthermore, when the coloring composition is prepared, the respective components constituting the coloring composition may be mixed together at the same time or mixed together sequentially after being dissolved and dispersed in a solvent. Further, the order of adding the components and the operation conditions during the mixing are not particularly restricted. For example, all the components may be dissolved and dispersed in a solvent at the same time to prepare the coloring composition. Alternatively, if desired, the respective components may be appropriately prepared as two or more solutions or dispersion liquids and mixed at the time of use (at the time of coating) to prepare the composition.

It is preferable that the coloring composition of the present invention is filtered using a filter for the purpose of removing impurities or reducing deficit, for example.

The filters that have been used in the related art for filtration use and the like may be used as a filter for filtration through a filter without particular limitation.

Examples of the materials of the filter include filters formed of a fluorine resin such as polytetrafluoroethylene (PTFE), a polyamide-based resin such as Nylon-6 and Nylon-6,6, and a polyolefin resin (including a high density and an ultrahigh molecular weight) such as polyethylene and polypropylene (PP). Among these materials, polypropylene (including high density polypropylene) is preferable.

The pore diameter of the filter is not particularly limited, and is, for example, approximately 0.01 μm to 20.0 μm, preferably approximately 0.01 μm to 5 μm, and more preferably approximately 0.01 μm to 2.0 μm.

By setting the pore diameter of the filter to the range, it is possible to remove fine particles more effectively, and thus to further reduce the turbidity.

Here, for the pore diameter of the filter herein, reference can be made to nominal values of filter manufacturers. A commercially available filter may be selected from various filters provided by, for example, Nihon Pall Corporation, Toyo Roshi Kaisha., Ltd., Nihon Entegris K.K. (formerly Nippon Microlith Co., Ltd.), Kitz Micro Filter Corporation, or the like.

In the filtration through a filter, two or more kinds of filters are used in combination.

For example, the filtration through a first filter may be followed by the next filtration through a second filter having a pore diameter different from that of the first filter.

At this time, each of the filtration through the first filter and the filtration through the second filter may be run once, or may be repeated twice or more times.

As the second filter, those formed of the same material as that of the above-described first filter may be used.

<Applications>

The coloring composition of the present invention is suitably used for forming a colored pattern of a color filter. Further, the coloring composition of the present invention can be suitably used for forming a colored pattern of a color filter or the like used in a solid-state imaging device (for example, a CCD and a CMOS) and an image display device such as a liquid crystal display device (LCD). Among these, the coloring composition can also be suitably used in an application of the manufacture of a color filter for a solid-state imaging device such as a CCD and a CMOS. In addition, the coloring composition of the present invention can be preferably used as a coloring composition for dry etching.

<Cured Film, Pattern Forming Method, Color Filter, and Method for Manufacturing Color Filter>

Next, the cured film, the pattern forming method, and the color filter in the present invention will be described in detail by an explanation of manufacturing methods thereof. Further, a method for manufacturing a color filter using the pattern forming method of the present invention will also be described.

The cured film of the present invention is formed by curing the coloring composition of the present invention. Such a cured film is preferably used in a color filter.

In the pattern forming method of the present invention, the coloring composition of the present invention is applied onto a support to form a coloring composition layer, and an undesired area is removed to form a colored pattern.

The pattern forming method of the present invention can be suitably applied for forming a colored pattern (pixel) included in a color filter.

With the coloring composition of the present invention, a pattern may be formed by a dry etching method and a color filter may be manufactured by forming a pattern using a so-called photolithography method.

That is, as a first embodiment of the pattern forming method of the present invention, a pattern forming method including a step of applying a coloring composition onto a support, followed by drying, to form a colored layer; a step of curing the colored layer; a step of forming a photoresist layer on the cured colored layer; a step of patterning the photoresist by exposing and developing the photoresist; and a step of patterning the colored layer of the underlayer of the photoresist by dry etching, using the patterned photoresist as an etching mask is exemplified.

In the case where the coloring composition of the present invention is used in a pattern forming method including a dry etching step, it may be a light or heat curable composition. In the case where the coloring composition is a heat curable composition, the compound having an epoxy group as described above is preferably used.

Moreover, as a second embodiment of the pattern forming method of the present invention, a pattern forming method including a step of applying a coloring composition onto a support to form a coloring composition layer, a step of patternwise exposing the coloring composition layer, and a step of removing an unexposed area by development to form a colored pattern is exemplified.

Such a pattern forming method is used for the manufacture of the colored layer of the color filter. That is, a method for manufacturing a color filter, including the pattern forming method of the present invention, is also disclosed in the present invention.

Hereinafter, details of these will be described.

The respective steps in the pattern forming method of the present invention will be described in detail below with reference to the method for manufacturing a color filter for a solid-state imaging device, but the present invention is not limited to this method. Hereinafter, the color filter for a solid-state imaging device may be simply referred to as a “color filter” in some cases.

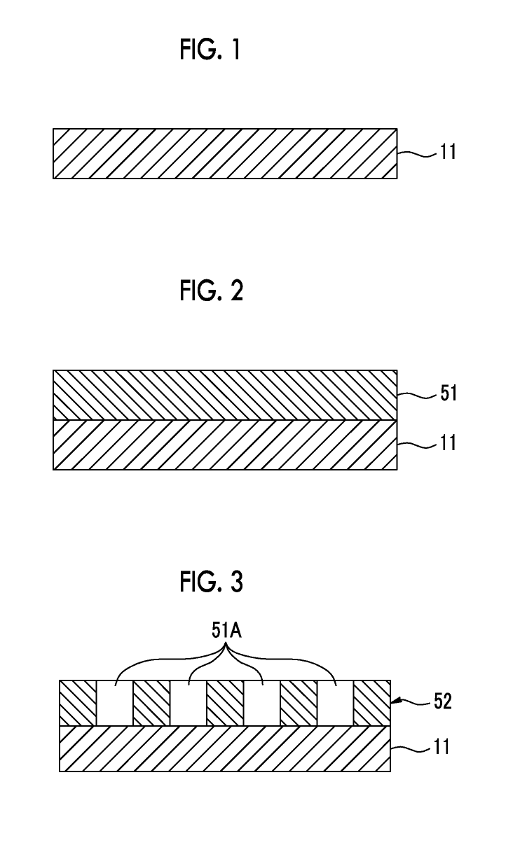

The method for manufacturing a color filter of the present invention will be described with reference to the specific examples thereof, using FIGS. 1 to 9.

First, as shown in the schematic cross-sectional view of FIG. 1, a first colored layer 11 is formed on a support not shown, using the coloring composition of the present invention (also referred to as a first coloring composition) (step (i)).

The first colored layer 11 can be formed by coating the coloring composition onto a support by a coating method such as spinning coating, slit coating, and spray coating, followed by drying, to form a colored layer.

The thickness of the first colored layer 11 is preferably in the range of 0.3 μm to 1.0 μm, more preferably in the range of 0.35 μm to 0.8 μm, and still more preferably in the range of 0.35 μm to 0.7 μm.

As a curing method, a method in which the first colored layer 11 is heated using a heating device such as a hot plate and an oven, followed by curing, is preferable. The heating temperature is preferably 120° C. to 250° C., and more preferably 160° C. to 230° C. The heating time varies depending on a heating means, but in the case of heating on a hot plate, the heating time is usually approximately 3 minutes to 30 minutes, and in the case of heating in an oven, the heating times is usually approximately 30 minutes to 90 minutes.

Next, patterning is performed by dry etching such that a through-hole group is formed in the first colored layer 11 (step (ii)).

The first colored pattern may be a colored pattern which is provided as a first tint on a support, and in some cases, may be a colored pattern which is provided as, for example, a pattern after a second tint or a third tint, on a support having a pattern already provided thereon.

The first colored layer 11 may be dry-etched using a patterned photoresist layer as a mask, and an etching gas. For example, as shown in schematic cross sectional view of FIG. 2, first, a photoresist layer 51 is formed over the first colored layer 11.

Specifically, a positive or negative type radiation-sensitive composition is applied (preferably coated) over the colored layer, and then dried to form the photoresist layer. In formation of the photoresist layer 51, it is preferable to further carry out a prebaking treatment. In particular, a process for forming a photoresist is preferably configured such that a post-exposure baking treatment (PEB) and a post-development baking treatment (post-baking treatment) are carried out.

As the photoresist, for example, a positive type radiation-sensitive composition is used. As the positive type radiation-sensitive composition, a positive type resist composition suitable for use in a positive type photoresist which is sensitive to radiations such as ultraviolet rays (a g-line, an h-line, an i-line), far ultraviolet radiations including excimer laser, electron beams, ion beams, and X-rays can be used. Among the radiations, the g-line, the h-line, and the i-line are preferable, among which the i-line is more preferable.

Specifically, as the positive type radiation-sensitive composition, a composition containing a quinone diazide compound and an alkali-soluble resin is preferable. The positive type radiation-sensitive composition containing a quinone diazide compound and an alkali-soluble resin makes use of a mechanism by which a quinone diazide group decomposes upon irradiation with light at 500 nm or less to generate a carboxyl group, and as a result, the composition changes from an alkali-insoluble one to an alkali-soluble one. The positive type photoresist has been used for manufacturing integrated circuits such as an IC and an LSI due to its notably excellent resolving power. Examples of the quinone diazide compound include a naphthoquinone diazide compound.

The thickness of a photoresist layer 51 is preferably 0.1 μm to 3 μm, more preferably 0.2 μm to 2.5 μm, and still more preferably 0.3 μm to 2 μm. Further, the photoresist layer 51 can be suitably coated by a coating method for the first colored layer 11 as described above.

Next, as shown in the schematic cross sectional view of FIG. 3, the photoresist layer 51 is exposed and developed to form a resist pattern (patterned photoresist layer) 52 having a resist through-hole group 51A provided therein.

The resist pattern 52 can be formed by appropriately optimizing any of photolithographic techniques known in the related art, without special limitation. By forming the resist through-hole group 51A in the photoresist layer 51 through exposure and development, the resist pattern 52 which serves as the etching mask in the subsequent etching may be provided on the first colored layer 11.

The photoresist layer 51 can be exposed by the positive or negative type radiation-sensitive composition with a g-line, an h-line, or an i-line, and preferably with an i-line, through a predetermined mask pattern. After the exposure, the photoresist is developed using a developing liquid, to be removed selectively in a region where the colored pattern will be formed.

As the developing liquid, any developing liquid can be used as long as it can dissolve an exposed area of the positive resist or an uncured area of the negative resist while not adversely affecting the first colored layer containing a colorant, and for example, combinations of various organic solvents or an alkaline aqueous solution can be used. As the alkaline aqueous solution, an alkaline aqueous solution which is prepared so as to control the concentration of an alkaline compound to 0.001% by mass to 10% by mass, and preferably 0.01% by mass to 5% by mass is suitable. Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, choline, pyrrole, piperidine, and 1,8-diazabicyclo[5.4.0]-7-undecene. Further, in the case of using the alkaline aqueous solution as the developing liquid, a treatment for cleaning with water is generally carried out after the development.

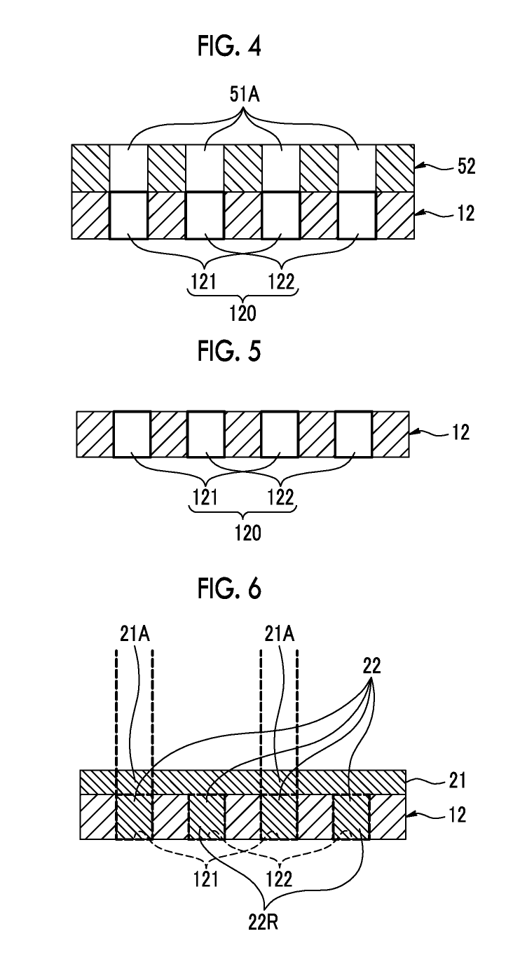

Next, as shown in the schematic cross sectional view of FIG. 4, the first colored layer 11 is patterned by dry etching, using the resist pattern 52 as an etching mask, so as to form the through-hole group 120. Thus, the first colored pattern 12 is formed. Here, the through-hole group 120 has a first through-hole subgroup 121 and a second through-hole subgroup 122.

The through-hole group 120 is provided in the first colored layer 11 so as to form a pane pattern. Accordingly, the first colored pattern 12, configured by providing the through-hole group 120 in the first colored layer 11, has a plurality of square first colored pixels arranged in a pane pattern.

Specifically, in the dry etching, the first colored layer 11 is dry-etched using the resist pattern 52 as the etching mask. Representative methods for dry etching include the methods described in JP1984-126506A (JP-S59-126506A), JP1984-46628A (JP-S59-46628A), JP1983-9108A (JP-S58-9108A), JP1983-2809A (JP-S58-2809A), JP1982-148706A (JP-S57-148706A), and JP1986-41102A (JP-S61-41102A).

The dry etching is preferably carried out in the following configurations, from the viewpoint of shaping the cross-section of the pattern more rectangular, and reducing damages to the support.

The etching step is preferably configured to include etching of the first step, in which the first colored layer 11 is etched using a mixed gas of a fluorine-based gas and oxygen gas (O₂), to a region (depth) where the support remains unexposed; the etching of the second step subsequent to the etching of the first step, in which the first colored layer 11 is etched using a mixed gas of nitrogen gas (N₂) and oxygen gas (O₂), preferably to a region (depth) where the support exposes; and over-etching subsequent to exposure of the support. Specific techniques of the dry etching, the etching of the first step, the etching of the second step, and the over-etching will be described below.

The dry etching is carried out according to etching conditions preliminarily determined by the following techniques.

(1) The etching rate (nm/min) in the etching of the first step, and the etching rate (nm/min) in the etching of the second step are respectively estimated.

(2) The time required for etching a desired thickness in the etching of the first step, and the time required for etching a desired thickness in the etching of the second step are respectively estimated.

(3) The etching of the first step is carried out according to the etching time estimated in (2).

(4) The etching of the second step is carried out according to the etching time estimated in (2). Alternatively, the etching time may be determined by endpoint detection, and the etching of the second step may be carried out according to the determined etching time.

(5) The over-etching time is estimated based on the total time of (3) and (4), based on which the over-etching is carried out.

The mixed gas used in the etching step of the first step preferably includes a fluorine-based gas and an oxygen gas (O₂), from the viewpoint of patterning an organic material which configures a film to be etched into a rectangular profile. By carrying out the etching step of the first step only to a range where the support remains unexposed, the support is prevented from being damaged.

Furthermore, after the etching step of the first step is carried out using a mixed gas of a fluorine-based gas and an oxygen gas, only up to the range where the support remains unexposed, the etching step of the second step and the over-etching step are preferably carried out using a mixed gas of a nitrogen gas and an oxygen gas, from the viewpoint of preventing damages of the support.

It is important to determine the ratio of the amount of etching in the etching step of the first step, and the amount of etching in the etching step of the second step, so as not to degrade the rectangularity obtained in the etching treatment of the etching step of the first step. The ratio of the amount of etching in the etching step of the second step, with respect to the total amount of etching (the total of the amount of etching in the etching step of the first step and the amount of etching in the etching step of the second step) preferably falls in the range of more than 0% and 50% or less, and preferably in the range of 10% to 20%. The amount of etching refers to the thickness of the film which remains etched.

Moreover, the etching preferably includes the over-etching treatment. The over-etching treatment is preferably carried out by setting the ratio of over-etching. Further, the ratio of over-etching is preferably estimated from the time of the etching treatment initially carried out. While the ratio of over-etching may arbitrarily be set, it is preferably 30% or less, more preferably 5% to 25%, and particularly preferably 10% to 15% of the etching time in the etching treatment in the etching step, from the viewpoint of etching resistance of the photoresist and maintainability of the rectangular etched pattern.

Next, as shown in the schematic cross-sectional view of FIG. 5, a resist pattern (that is, an etching mask) 52 which remains after the etching is removed. The removal of the resist pattern 52 preferably includes a step of applying a stripping liquid or a solvent over the resist pattern 52 to make the resist pattern 52 ready for removal, and a step of removing the resist pattern 52 using cleaning water.

Examples of the step of applying a stripping liquid or a solvent onto the resist pattern 52 to make the resist pattern 52 ready for removal include a step of applying a stripping liquid or a solvent at least onto the resist pattern 52, and allowing it to stay for a predetermined time for puddle development. The time over which the stripping liquid or solvent is allowed to stay is preferably several tens of seconds to several minutes, but not particularly limited.

Furthermore, examples of the step of removing the resist pattern 52 using cleaning water include a step of removing the resist pattern 52 by spraying the cleaning water from a spray-type or shower-type jetting nozzle against the resist pattern 52. Pure water is preferably used as the cleaning water. Further, examples of the jetting nozzle include a jetting nozzle capable of covering the entire support within the range of jetting thereof, and a movable jetting nozzle capable of covering the entire support within the movable range thereof. The jetting nozzle, in the case of being configured as the movable type one, can remove the resist pattern 52 more effectively in the step of removing the resist pattern 52, by jetting the cleaning water while travelling from the center of the support to the end of the support twice or more times.

The stripping liquid generally contains an organic solvent, and may further contain an inorganic solvent. Examples of the organic solvent include by 1) a hydrocarbon-based compound, 2) a halogenated hydrocarbon-based compound, 3) an alcohol-based compound, 4) an ether or acetal-based compound, 5) a ketone- or aldehyde-based compound, 6) an ester-based compound, 7) a polyhydric alcohol-based compound, 8) a carboxylic acid or its acid anhydride-based compound, 9) a phenol-based compound, 10) a nitrogen-containing compound, 11) a sulfur-containing compound, and 12) a fluorine-containing compound. The stripping liquid preferably contains the nitrogen-containing compound, and more preferably contains the noncyclic nitrogen-containing compound and the cyclic nitrogen-containing compound.

The noncyclic nitrogen-containing compound is preferably a noncyclic nitrogen-containing compound having an hydroxyl group. Specific examples thereof include monoisopropanolamine, diaisopropanolamine, triisopropanolamine, N-ethylethanolamine, N,N-dibutylethanolamine, N-butylethanolamine, monoethanolamine, diethanolamine, and triethanolamine; preferably monoethanolamine, diethanolamine, and triethanolamine; and more preferably monoethanolamine (H₂NCH₂CH₂OH). Further, examples of the cyclic nitrogen-containing compound include isoquinoline, imidazole, N-ethylmorpholine, ∈-caprolactam, quinoline, 1,3-dimethyl-2-imidazolidinone, α-picoline, β-picoline, γ-picoline, 2-pipecoline, 3-pipecoline, 4-pipecoline, piperazine, piperidine, pyrazine, pyridine, pyrrolidine, N-methyl-2-pyrrolidone, N-phenylmorpholine, 2,4-lutidine, and 2,6-lutidine; preferably N-methyl-2-pyrrolidone, and N-ethylmorpholine; and more preferably N-methyl-2-pyrrolidone (NMP).

The stripping liquid preferably includes the noncyclic nitrogen-containing compound and the cyclic nitrogen-containing compound; more preferably includes at least one species selected from monoethanolamine, diethanolamine, or triethanolamine as the noncyclic nitrogen-containing compound, and at least one species selected from N-methyl-2-pyrrolidone and N-ethylmorpholine as the cyclic nitrogen-containing compound; and still more preferably includes monoethanolamine and N-methyl-2-pyrrolidone.

The removal using the stripping liquid will suffice if the resist pattern 52 formed on the first colored pattern 12 is removed, in which deposited matter may not be completely removed in the case where the deposited matter as an etching product is adhered onto the side wall of the first colored pattern 12. The deposited matter is an etching product adhered and accumulated on the side wall of the colored layer.

The stripping liquid preferably has a content of the noncyclic nitrogen-containing compound of 9 parts by mass or more and 11 parts by mass or less, with respect to 100 parts by mass of the stripping liquid, and has a content of the cyclic nitrogen-containing compound of 65 parts by mass or more and 70 parts by mass or less, with respect to 100 parts by mass of the stripping liquid. Further, the stripping liquid is preferably a mixture of the noncyclic nitrogen-containing compound and the cyclic nitrogen-containing compound, which has been diluted with pure water.

Next, as shown in the schematic cross-sectional view of FIG. 6, a second colored layer 21 is laminated on the first colored layer (that is, the first colored pattern 12 configured by forming the through-hole group 120 in the first colored layer 11) using the second coloring composition, so as to fill up the individual through-holes in the first through-hole subgroup 121 and in the second through-hole subgroup 122 with the second coloring composition, thereby forming a plurality of second colored pixels (step (iii)). Thus, a second colored pattern 22, configured by a plurality of second colored pixels, is formed in the through-hole group 120 of the first colored layer 11. Here, the second colored pixels are given as square pixels. The second colored layer 21 can be formed by the same method as that for forming the first colored layer 11 described above.

The thickness of the second colored layer 21 is preferably in the range of 0.3 μm to 1 μm, more preferably in the range of 0.35 μm to 0.8 μm, and still more preferably in the range of 0.35 μm to 0.7 μm.

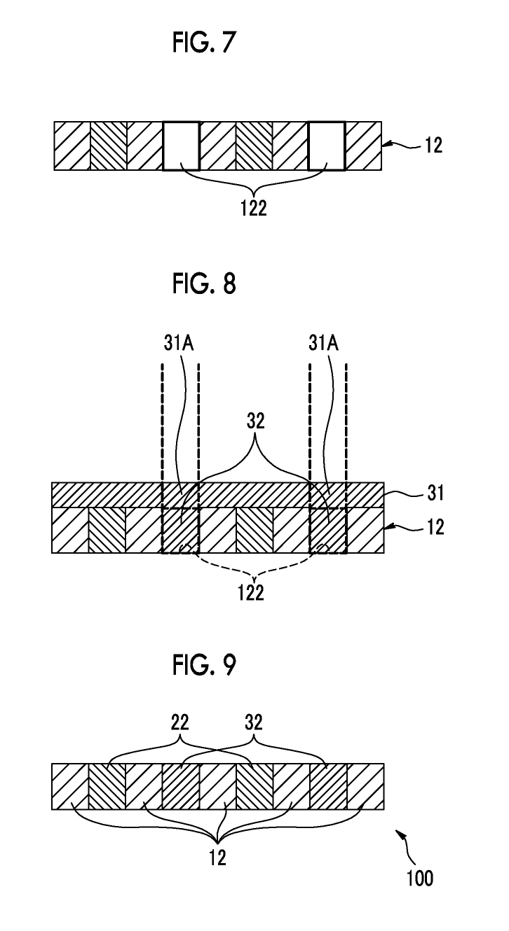

Furthermore, a region 21A of the second colored layer 21, corresponding to the first through-hole subgroup 121 provided in the first colored layer 11, is exposed and developed to remove the second colored layer 21 and a plurality of second colored pixels 22R provided inside the individual through-holes in the second through-hole subgroup 122 (step (iv)) (see the schematic cross-sectional view of FIG. 7).

Next, as shown in the schematic cross-sectional view of FIG. 8, a third colored layer 31 is formed on the first colored layer (that is, the first colored pattern 12 configured by forming the second colored pattern 22 in the first through-hole subgroup 121) using the third coloring composition, so as to fill up the individual through-holes in the second through-hole subgroup 122 with the third coloring composition, thereby forming a plurality of third colored pixels (step (v)). Thus, a third colored pattern 32, configured by a plurality of third colored pixels, is formed in the second through-hole subgroup 122 of the first colored layer 11. Here, the third colored pixels are given as square pixels. The third colored layer 31 can be formed by the same method as that for forming the first colored layer 11 described above.

The thickness of the third colored layer 31 is preferably in the range of 0.3 μm to 1 μm, more preferably in the range of 0.35 μm to 0.8 μm, and still more preferably in the range of 0.35 μm to 0.7 μm.

Moreover, a region 31A of the third colored layer 31, corresponding to the second through-hole subgroup 122 provided in the first colored layer 11, is exposed and developed to remove the third colored layer 31, thereby manufacturing a color filter 100 having the first colored pattern 12, the second colored pattern 22, and the third colored pattern 32 is manufactured, as shown in the schematic cross-sectional view of FIG. 9 (step (vi)).

Each of the second coloring composition and the third coloring composition as described above contains a colorant. Examples of the colorant include those mentioned above regarding the coloring composition of the present invention. However, in a preferred embodiment, one of the second colored pixel and the third colored pixel forms a red transmission portion, and the other forms a blue transmission portion, and therefore, it is preferable that both of the colored pixels are a red transmission portion and a blue transmission portion, respectively. The colorant contained in the coloring composition for forming the red transmission portion is at least one selected from those described in paragraphs Nos. 0037 and 0039 of JP2012-172003A, the contents of which are incorporated herein by reference. The colorant contained in the coloring composition for forming the blue transmission portion is preferably one or more selected from C. I. Pigment Violet 1, 19, 23, 27, 32, 37, and 42, and C. I. Pigment Blue 1, 2, 15, 15:1, 15:2, 15:3, 15:4, 15:6, 16, 22, 60, 64, 66, 79, and 80.

In each of the second coloring composition and the third coloring composition, the content of the colorant with respect to the total solid content of the composition of the colorant is preferably 30% by mass or more, more preferably 35% by mass or more, and still more preferably 40% by mass or more. Further, the content of the colorant with respect to the total solid content of the composition of the colorant is usually 90% by mass or less, and preferably 80% by mass or less.

Furthermore, as each of the second coloring composition and the third coloring composition, a negative type radiation-sensitive composition is preferably used. As this negative type radiation-sensitive composition, a negative type radiation-sensitive composition which is sensitive to radiations such as ultraviolet rays (a g-line, an h-line, and an i-line), far ultraviolet radiation including excimer laser, electron beams, ion beams, and X-rays can be used. Among these radiations, the g-line, the h-line, and the i-line are preferable, among which the i-line is preferable.

Specifically, as the negative type radiation-sensitive composition, a negative type radiation-sensitive composition containing a photopolymerization initiator, a polymerizable component (polymerizable compound), a binder resin (an alkali-soluble resin or the like), and the like are preferable, and examples thereof include those described in paragraph Nos. “0017” to “0064” of JP2005-326453A. Such a negative type radiation-sensitive composition makes use of a mechanism by which the photopolymerization initiator initiates a polymerization reaction of the polymerizable compound upon irradiation with radiations, and as a result, the composition changes from an alkali-soluble one to an alkali-insoluble one.

The second colored layer 21 and the third colored layer 31 can be exposed using a g-line, an h-line, or an i-line, and preferably using an i-line.

Furthermore, the development subsequent to the exposure is usually carried out by a development treatment using a developing liquid.

Examples of the developing liquid include those described above in the exposure and the development for the photoresist layer 51.

In addition, in the case of using the alkaline aqueous solution as the developing liquid, a treatment for cleaning with water is generally carried out after the development.

Each of the first colored pixels, the second colored pixels, and the third colored pixels preferably have a length of one side (a short side in the case of a rectangular pixel and a side in the case of a square pixel) of 0.5 μm to 1.7 μm, and more preferably 0.6 μm to 1.5 μm, from the viewpoint of an image resolution.

<Pattern Forming Method Using Coloring Composition Layer by Photolithography Method>

In the method for manufacturing a color filter of the present invention, pattern formation can be carried out using a coloring composition layer by a photolithography method. For details of the photolithography method, reference can be made to paragraph Nos. 0173 to 0188 of JP2013-227497A, the contents of which will be incorporated herein by reference.

Since the color filter of the present invention is formed by the coloring composition having a high concentration of colorants, the colored pattern can be extremely thinned (for example, 0.7 μm or less).

The color filter of the present invention can be suitably used for a solid-state imaging device such as a CCD and an CMOS, and is suitable for a CCD, a CMOS, or the like having a high resolution exceeding 1,000,000 pixels. The color filter for a solid-state imaging device of the present invention can be used as a color filter disposed, for example, between a light receiving section of each pixel constituting the CCD or the CMOS, and a microlens for collecting light.

The film thickness of the colored pattern (colored pixel) in the color filter of the preset invention is preferably 0.1 μm to 1.0 μm, and more preferably 0.1 μm to 0.8 μm. Since the concentration of the colorants in the colored pattern in the present invention can be increased, such a film can be thinned.

In addition, the size (pattern width) of the colored pattern (colored pixel) is preferably 2.5 μm or less, more preferably 2.0 μm or less, and particularly preferably 1.7 μm or less.

<Solid-State Imaging Device>

The solid-state imaging device of the present invention includes the color filter of the present invention as described above. The constitution of the solid-state imaging device of the present invention is not particularly limited as long as the solid-state imaging device is constituted to include the color filter in the present invention and functions as a solid-state imaging device. However, for example, the solid-state imaging device can be constituted as below.

The solid-state imaging device has a configuration which has a plurality of photodiodes constituting a light-receiving area of a solid-state imaging device (a CCD image sensor, a CMOS image sensor, or the like) and a transfer electrode formed of polysilicon or the like, on a support; a light shielding film formed of tungsten or the like onto the photodiodes and the transfer electrodes, which has openings only over the light receiving section of the photodiode; a device protecting film formed of silicon nitride or the like, which is formed to cover the entire surface of the light shielding film and the light receiving section of the photodiodes, on the light shielding film; and the color filter for a solid-state imaging device of the present invention on the device protecting film.

In addition, the solid-state imaging device may have a configuration in which a light-collecting means (for example, a micro lens or the like, which applies hereinafter) is disposed on the device protective layer and under the color filter (a side closer to the support), a configuration in which a light-condensing means is disposed on the color filter, and the like.

<Image Display Device>

The color filter of the present invention can be used not only for a solid-state imaging device, but also for an image display device such as a liquid crystal display device and an organic EL display device. In particular, the color filter is suitable in the applications of a liquid crystal display device. The liquid crystal display device comprising the color filter of the present invention can display a high-quality image showing a good tint of a display image and having excellent display characteristics.

The definition of display devices or details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989), and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and for example, the present invention can be applied to liquid crystal display devices employing various systems described in the “Liquid Crystal Display Technology for Next Generation”.

The color filter of the present invention may be used for a liquid crystal display device using a color TFT system. The liquid crystal display device using a color TFT system is described in, for example, “Color TFT Liquid Crystal Display (KYORITSU SHUPPAN Co., Ltd., published in 1996)”. Further, the present invention can be applied to a liquid crystal display device having an enlarged view angle, which uses an in-plane switching mode such as IPS and a pixel division system such as MVA, or to STN, TN, VA, OCS, FFS, R-OCB, and the like.

In addition, the color filter in the present invention can be provided to a Color-filter On Array (COA) system which is a bright and high-definition system. In the liquid crystal display device of the COA system, the characteristics required for a color filter layer need to include characteristics required for an inter layer insulating film, that is, a low dielectric constant and resistance to a peeling solution in some cases, in addition to the generally required characteristics as described above. In the color filter of the present invention, by using a colorant having an excellent hue, the color purity, light-transmitting properties, and the like are excellent, and the tone of the colored pattern (pixel) is excellent. Consequently, a liquid crystal display device of a COA system which has a high resolution and is excellent in long-term durability can be provided. Further, in order to satisfy the characteristics required for a low dielectric constant, a resin coat may be provided on the color filter layer.

These image display systems are described in, for example, p. 43 of “EL, PDP, and LCD Display Technologies and Recent Trend in Market (TORAY RESEARCH CENTER, Research Department, published in 2001)”, and the like.

The liquid crystal display device comprising the color filter in the present invention is constituted with various members such as an electrode substrate, a polarizing film, a retardation film, a backlight, a spacer, and a view angle compensation film, in addition to the color filter of the present invention. The color filter of the present invention can be applied to a liquid crystal display device constituted with these known members. These members are described in, for example, “'94 Market of Peripheral Materials And Chemicals of Liquid Crystal Display (Kentaro Shima, CMC Publishing Co., Ltd., published in 1994)” and “2003 Current Situation of Market Relating to Liquid Crystal and Prospects (Vol. 2) (Ryokichi Omote, Fuji Chimera Research Institute, Inc., published in 2003)”.

The backlight is described in SID Meeting Digest 1380 (2005) (A. Konno, et al.), December Issue of Monthly “Display”, 2005, pp. 18 to 24 (Yasuhiro Shima) and pp. 25 to 30 (Takaaki Yagi) of the document, and the like.

If the color filter in the present invention is used in a liquid crystal display device, high contrast can be realized when the color filter is combined with a three-wavelength tube of a cold cathode tube known in the related art. Further, if a light source of LED in red, green, and blue (RGB-LED) is used as a backlight, a liquid crystal display device having high luminance, high color purity, and good color reproducibility can be provided.

### EXAMPLES

Hereinbelow, the present invention will be described in more detail with reference to Examples. The materials, amounts of use, proportions, treatment details, treatment procedures, and the like shown in Examples below can be modified as appropriate without departing from the spirit of the present invention. Therefore, the scope of the present invention is not intended to be limited to the specific examples shown below. Further, “part(s)” and “%” are given on the basis of mass unless otherwise specifically stated.

### Synthesis Example 1

### Synthesis of Halogenated Zinc Phthalocyanine Pigment

Using phthalonitrile, ammonia, and zinc chloride as raw materials, zinc phthalocyanine was produced.

For halogenations of zinc phthalocyanine, 45.5 parts of sulfuryl chloride, 54.5 parts of anhydrous aluminum chloride, and 7 parts of sodium chloride were mixed at 40° C., and 15 parts of a zinc phthalocyanine pigment was added thereto. 35 parts of bromine was added dropwise thereto, and the mixture was warmed to 130° C. for 19.5 hours and kept at that temperature for 1 hour. Thereafter, the reaction mixture was taken out of water to precipitate a crude halogenated zinc phthalocyanine pigment. This aqueous slurry was filtered, washed with warm water at 60° C., with a 1% aqueous sodium hydrogen sulfate solution, and with warm water at 60° C., and dried at 90° C. to obtain 2.7 parts of a purified, crude halogenated zinc phthalocyanine pigment A.

1 part of the purified, crude halogenated zinc phthalocyanine pigment A, 10 parts of pulverized sodium chloride, and 1 part of diethylene glycol were put into a double-arm type kneader, and kneaded at 100° C. for 8 hours. The kneaded product was taken out of 100 parts of water at 80° C., stirred for 1 hour, filtered, washed with warm water, dried, and pulverized to obtain a halogenated zinc phthalocyanine pigment.

The halogenated zinc phthalocyanine pigment thus obtained was found to have an average composition of ZnPcBr_{9.8}Cl_{3.1}H_{3.1} through mass spectrometry and halogen content analysis by flask combustion ion chromatography. Further, Pc is an abbreviation of phthalocyanine.

### Synthesis Example 2

### Synthesis of Siloxane Resin

47.6 g (0.35 mol) of methyltrimethoxysilane, 29.7 g (0.15 mol) of phenyltrimethoxysilane, and 100 g of γ-butyrolactone were put into a reaction container, and to this solution were added 30.6 g of water and 0.48 g of phosphoric acid under stirring. Methanol was removed therefrom by distillation by heating for appropriate preparation. Thus, siloxane resins 1 to 4 having a solid content of 40% were synthesized at the ratios shown in Table 1 below.

Furthermore, by changing parts of methyltrimethoxysilane to tetramethoxysilane, siloxane resins 5 and 7 were synthesized.

In addition, by changing parts of methyltrimethoxysilane to dimethyldimethoxysilane, siloxane resins 6 and 8 were synthesized.

The ratios of the Si—OH bonds, the Si—OR bonds, and the Si—R bonds to the Si atoms in the obtained siloxane resin were calculated from the area ratios of the peaks by NMR measurement. (R represents a methyl group or a phenyl group)

TABLE 1

| | Siloxane | Siloxane | Siloxane | Siloxane | Siloxane | Siloxane | Siloxane | Siloxane |
|---|---|---|---|---|---|---|---|---|
| | resin 1 | resin 2 | resin 3 | resin 4 | resin 5 | resin 6 | resin 7 | resin 8 |
| Number of Si—R | 1.00 | 1.00 | 1.00 | 1.00 | 0.85 | 1.15 | 0.70 | 1.30 |
| bonds per Si atom | | | | | | | | |
| Sum of numbers | 0.50 | 0.70 | 1.20 | 0.15 | 0.65 | 0.35 | 0.80 | 0.20 |
| of Si—OH bonds | | | | | | | | |
| and Si—OR bonds | | | | | | | | |
| per Si atom | | | | | | | | |

### Examples 1 to 6, and Comparative Examples 1 and 2

### Preparation of Green Pigment Dispersion Liquid

A mixed liquid of 7.15 parts of the halogenated zinc phthalocyanine pigment obtained in Synthesis Example 1, 7.15 parts of Pigment Yellow 150, 1.4 parts of a pigment derivative A, 4.3 parts of a dispersing agent A, and 80 parts of propylene glycol monomethyl ether acetate (PGMEA) was mixed and dispersed by a bead mill for 15 hours to prepare a green pigment dispersion liquid 1.

<Preparation of Green Pigment-Containing Coloring Composition (Coating Liquid)>

Using the green pigment dispersion liquid, the components were mixed and stirred such that the following composition was obtained, thereby preparing a green pigment-containing coloring composition.

<Composition>

| | |
|---|---|
| Pigment dispersion liquid: Green pigment dispersion liquid | 89.2 parts |
| Siloxane resin described in Table 2 (solution having a | 3 parts |
| solid content of 40%) | |
| Curable compound: Epoxy compound A | 0.96 parts |
| Solvent: PGMEA | 6.64 parts |
| Surfactant: 0.2% solution of F-781 (manufactured | 3.0 parts |
| by DIC Corporation) (polymer type surfactant: | |
| mass-average molecular weight of 30,000, solid | |
| content acid value of 0 mgKOH/g) in PGMEA | |

Pigment derivative A: The structure shown below

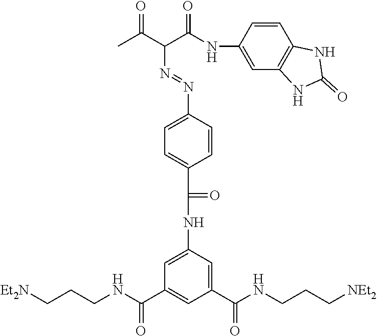

Dispersing agent A: The structure shown below (the numeral values denoted also in the respective structural units (the numeral values denoted also in the repeating units of the main chain) represent the contents [unit: % by mass] of the respective structural units. The numeral value also described in the repeating moiety of the side chain represents the repetition number of the repeating moieties).

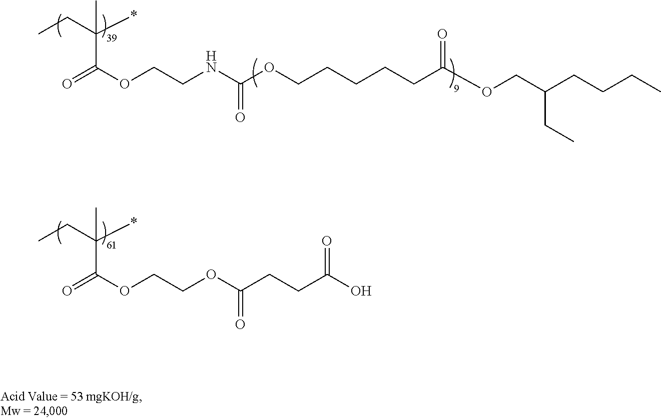

Epoxy compound A: The structure shown below, 1,2-epoxy-4-(2-oxiranyl)cyclohexane adduct of 2,2-bis(hydroxymethyl)-1-butanol (manufactured by Daicel Corporation, EHPE3150, Mw 23,000). In the following structure, the substitution of the epoxy group is at an arbitrary position.

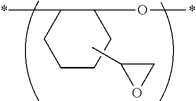

<Preparation of Blue Pigment Dispersion Liquid>

A mixed liquid composed of 9.5 parts of a Pigment Blue 15:6 and 2.4 parts of Pigment Violet 23 as pigments, 5.6 parts of BYK-161 (manufactured by BYK) as a resin, and 82.5 parts of propylene glycol monomethyl ether acetate (PGMEA) as a solvent was mixed and dispersed by a beads mill for 15 hours, thereby preparing a blue pigment dispersion liquid.

<Preparation of Blue Pigment-Containing Coloring Composition (Coating Liquid>

Using the blue pigment dispersion liquid, the components were mixed and stirred such that the following composition was obtained, thereby preparing a blue pigment-containing coloring composition (blue coloring radiation-sensitive composition).

<Composition>

| | |
|---|---|
| Pigment dispersion liquid: Blue pigment dispersion liquid | 51.2 parts |
| Photopolymerization initiator: IRGACURE OXE-01 | 0.87 parts |
| (manufactured by BASF) | |
| Polymerizable compound: KAYARAD RP-1040 | 4.7 parts |
| (manufactured by Nippon-Kayaku Co., Ltd.) | |
| Binder: ACA230AA (manufactured by Daicel Chemical | 7.4 parts |
| Industries, Ltd.) | |
| Polymerization inhibitor: p-Methoxyphenol | 0.002 parts |
| Non-ionic surfactant: PIONIN D-6112-W (manufactured | 0.19 parts |
| by TAKEMOTO OIL & FAT CO., LTD.) | |
| Silane coupling agent: a 0.9% solution of KBM-602 | 10.8 parts |
| (manufactured by Shin-Etsu Chemical Co., Ltd.) | |
| in cyclohexanone | |
| Organic solvent: PGMEA | 14.3 parts |
| Organic solvent: cyclohexanone | 6.4 parts |
| Fluorine-based surfactant: a 0.2% solution of F-781 | 4.2 parts |
| (manufactured by DIC) in cyclohexanone | |

<Manufacture of Cured Film>

The green pigment-containing coloring composition was coated onto a 6-inch silicon wafer and a glass substrate such that a coated film having a film thickness of 0.53 μm was obtained, and then heated at 200° C. for 5 minutes using a hot plate, and the coated film was cured, thereby forming a colored layer. The film thickness of the green colored layer was 0.5 km.

<Evaluation of Colorfastness>

The absorbance at a wavelength of 450 nm of the colored layer that had been cured on the glass substrate was measured by MCPD-3000 (manufactured by Otsuka Electronics, Co., Ltd.) (Abs1).

Next, a glass substrate having a colored layer attached thereto was immersed in FHD-5, a developing liquid manufactured by FUJIFILM Electronic Materials Co., Ltd. for 5 minutes. The substrate was taken out of the developing liquid after immersion, subjected to a rinsing treatment with pure water for 20 seconds, and then spray-dried, and subsequently, an absorbance at a wavelength of 450 nm was measured with MCPD-3000 (Abs2).

The colorfastness was determined in accordance with the criteria as follows from the change in absorbance between before and after the immersion in the developing liquid. A to C indicate practical levels in accordance with the following criteria.

A: 0.98<(Abs2/Abs1)

B: 0.95<(Abs2/Abs1)≦0.98

C: 0.90<(Abs2/Abs1)≦0.95

D: 0.80<(Abs2/Abs1)≦0.90

E: (Abs2/Abs1)<0.80

<Manufacture of Color Filter>

(Dry Etching Step)

The green pigment-containing coloring composition was coated onto a 8-inch silicon wafer substrate, using a spin coater, such that that a coated film having a film thickness of 0.53 μm was obtained, and then heated at 200° C. for 5 minutes using a hot plate, and the coated film was cured, thereby forming a first colored layer (green layer). The film thickness of the first colored layer (green layer) was 0.5 μm.

(Coating of Resist for Mask)

Next, a positive type photoresist “Fhi-622BC” (manufactured by FUJIFILM Electronic Materials Co., Ltd.) was coated and pre-baked, thereby forming a photoresist layer having a film thickness of 0.8 μm.

Next, the photoresist layer was subjected to a heating treatment at a temperature capable of keeping the temperature of photoresist layer or the ambient temperature at 90° C. for 1 minute. Thereafter, the photoresist layer was subjected to a developing treatment using a developing liquid “FHD-5” (manufactured by FUJIFILM Electronic Materials Co., Ltd.) for 1 minute, and further subjected to a post-baking treatment at 110° C. for 1 minute.

(Dry Etching)

Next, dry etching was carried out by the following procedure.

A first step of an etching treatment was carried out for 80 seconds, using a dry etcher (U-621, manufactured by Hitachi, Ltd.), under the conditions of an RF power of 800 W, an antenna bias of 400 W, a wafer bias of 200 W, an internal pressure of a chamber of 4.0 Pa, a substrate temperature of 50° C., and gas kinds and flow rates of mixed gases of CF₄: 80 mL/min., O₂: 40 mL/min., and Ar: 800 mL/min.

Next, a second step of the etching treatment and the over-etching treatment were carried out for 28 seconds in the same etching chamber, under the conditions of an RF power of 600 W, an antenna bias of 100 W, a wafer bias of 250 W, an internal pressure of a chamber of 2.0 Pa, a substrate temperature of 50° C., and gas kinds and flow rates of mixed gases of N₂=500 mL/min., O₂=50 mL/min., and Ar=500 mL/min. (N₂/O₂/Ar=10/1/10).

After the dry etching was carried out under the conditions, the resist was removed by carrying out a stripping treatment using a photoresist stripping liquid “MS230C” (manufactured by FUJIFILM Electronic Materials Co., Ltd.) for 120 seconds. The residue was further washed with pure water, spin-dried, and then subjected to a baking treatment for dehydration at 100° C. for 2 minutes, thereby obtaining a first color filter (green layer).

<Formation of Second Colored Layer>

A blue pigment-containing coloring composition was applied onto the first colored layer (green layer) obtained above such that the thickness after drying and post-baking became 0.40 μm, and dried, thereby obtaining a laminated color filter in which a second colored layer (blue layer) was formed on the first colored layer (green layer).

Next, the laminated color filter thus obtained was loaded on a horizontal rotation table of a spin-shower developer (DW-30 Type, manufactured by Chemitronics Co., Ltd.), and was subjected to a puddle development at 23° C. for 60 seconds using a 60% dilution of CD-2000 (manufactured by Fujifilm Electronic Materials Co., Ltd.).

The silicon wafer after the development was fixed on the horizontal rotation table in a vacuum chuck manner. While the silicon wafer was rotated at 50 rpm by a rotation device, it was subjected to a rinsing treatment by supplying pure water in a shower type from the ejection nozzle above the reaction center, followed by spray-drying, and the second colored layer was removed by development. Then, a post-baking treatment was carried out at 220° C. for 5 minutes.

<Evaluation of Lamination>

The substrate after the post-baking of the second colored layer was 20,000-fold magnified, using a critical dimension SEM (S-9260 scanning electron microscope manufactured by manufactured by Hitachi, Ltd.), and the patterning performance of the second colored layer (blue layer) laminated between the patterns of the first colored layer (green layer) was confirmed.

A: There was no warping in the wafer, and the pattern shape after the dry etching of the first colored layer (green layer) and the pattern shape of the second colored layer (blue layer) were good.

B: When the first colored layer (green layer) was formed by curing the green pigment-containing coloring composition, warping occurred in the wafer, and at the time of alignment upon the overlay exposure of the second colored layer (blue layer), alignment errors of the exposure machine occurred. Thus, the second colored layer could not be patterned.

<Evaluation of Development Residues>

The substrate after the post-baking of the second colored layer was 20,000-fold magnified, using a critical dimension SEM (S-9260 scanning electron microscope manufactured by Hitachi, Ltd.), and the presence or absence of the development residues of the blue pigment-containing coloring composition on the first colored layer (green layer) was confirmed.

A: There was no development residue of the blue pigment-containing coloring composition on the first colored layer (green layer).

B: There were development residues of the blue pigment-containing coloring composition attached onto the first colored layer (green layer).

TABLE 2

| | | | | Comparative | Comparative | | | | |
|---|---|---|---|---|---|---|---|---|---|
| | | Example 1 | Example 2 | Example 1 | Example 2 | Example 3 | Example 4 | Example 5 | Example 6 |
| Siloxane | Type | Siloxane | Siloxane | Siloxane | Siloxane | Siloxane | Siloxane | Siloxane | Siloxane |
| resin | | resin 1 | resin 2 | resin 3 | resin 4 | resin 5 | resin 6 | resin 7 | resin 8 |
| | Number of Si—R | 1.00 | 1.00 | 1.00 | 1.00 | 0.85 | 1.15 | 0.70 | 1.30 |
| | bonds per Si atom | | | | | | | | |
| | Sum of numbers | 0.50 | 0.70 | 1.20 | 0.15 | 0.65 | 0.35 | 0.80 | 0.20 |
| | of Si—OH bonds | | | | | | | | |
| | and Si—OR bonds | | | | | | | | |
| | per Si atom | | | | | | | | |

| | | | | | | | | |
|---|---|---|---|---|---|---|---|---|
| Colorfastness | B | A | A | E | A | C | B | C |
| Evaluation of laminating properties | A | A | B | A | A | A | A | A |
| Evaluation of development residues | A | A | A | B | A | A | A | A |

As clearly seen from the above table, with the coloring compositions of Examples 1 to 6, warping did not occur in the wafer to which the coloring composition had been applied, and thus, the laminating properties were evaluated as good. Further, a cured film having excellent colorfastness could be formed, as compared with Comparative Example 2 in which a siloxane resin having a sum of the numbers of Si—OH bonds and Si—OR bonds per silicon atom of less than 0.2 was used. In addition, there was no development residue of the blue pigment-containing coloring composition on the first colored layer (green layer).

On the other hand, in Comparative Example 1 in which a siloxane resin having a sum of the numbers of Si—OH bonds and Si—OR¹ bonds per silicon atom of 1.0 or more was used, warping occurred in the wafer to which the coloring composition had been applied and alignment errors of the exposure machine occurred at a time of alignment upon the overlay exposure of the second colored layer (blue layer). Thus, the second colored layer could not be patterned.

### EXPLANATION OF REFERENCES

11: First colored layer
12: First colored pattern
21: Second colored layer
21A: Position corresponding to the first through-hole sub group 121
22: Second colored pattern
22R: Plurality of the second colored pixels provided inside individual through-holes in the second through-hole sub group 122
31: Third colored layer
31A: Position corresponding to the second removing section group 122
32: Third colored pattern
51: Photoresist layer
51A: Resist removing section
52: Resist pattern (patterned photoresist layer)
120: Through-hole group
121: First through-hole sub group
122: Second through-hole sub group

What is claimed is:

1. A coloring composition comprising:
a colorant; and
a resin,
wherein the content of the colorant with respect to the total solid content of the coloring composition is 60% by mass or more,
the resin contains a siloxane resin containing Si—OH bonds and Si—OR¹ bonds, wherein R¹ represents an alkyl group or an aryl group, in the total number of 0.2 to 1.0 bonds per silicon atom,
and
the content of the siloxane resin with respect to the total solid content of the coloring composition is 1% by mass to 20% by mass.

2. The coloring composition according to claim 1, wherein the siloxane resin contains 0.6 to 1.5 Si—R² bonds, in which R² represents an alkyl group or an aryl group, per silicon atom.

3. The coloring composition according to claim 1, further comprising a curable compound.

4. The coloring composition according to claim 1, wherein the colorant contains at least a halogenated zinc phthalocyanine pigment.

5. The coloring composition according to claim 1, for use in formation of a colored layer of a color filter.

6. A cured film formed by curing the coloring composition according to claim 1.

7. A color filter comprising the cured film according to claim 6.

8. A pattern forming method comprising:
applying the coloring composition according to claim 1 onto a support, followed by drying, to form a colored layer;
curing the colored layer;
forming a photoresist on the cured colored layer;
patterning the photoresist by exposing and developing the photoresist; and
patterning the colored layer of the underlayer of the photoresist by dry etching, using the patterned photoresist as an etching mask.

9. A method for manufacturing a color filter having a plurality of colored layers formed on a substrate, comprising:
forming the pattern of a first colored layer in accordance with the method according to claim 8; and
forming another colored pattern by lithography on the first colored layer thus patterned.

10. A solid-state imaging device comprising the color filter according to claim 7.

11. An image display device comprising the color filter according to claim 7.
